(19) United States
(12) Patent Application Publication
(10) Pub. No.: US 2009/0090949 A1
(43) Pub. Date: Apr. 9, 2009

(54) SEMICONDUCTOR DEVICE AND METHOD OF MANUFACTURING THE SAME

(75) Inventor: Noriaki MIKASA, TOKYO (JP)

Correspondence Address: YOUNG & THOMPSON, 209 Madison Street, Suite 500, ALEXANDRIA, VA, 22314, US

(73) Assignee: ELIPIDA MEMORY, INC., TOKYO (JP)

(21) Appl. No.: 12/244,805

(22) Filed: Oct. 3, 2008

(30) Foreign Application Priority Data
Oct. 9, 2007 (JP) 2007-263248

(51) Int. Cl. H01L 29/94; H01L 21/8242

(52) U.S. Cl. 257/296; 438/239; 257/E29.345; 257/E21.646

(57) ABSTRACT

A semiconductor device includes: an active region insulated by an element-isolation insulating film embedded on a semiconductor substrate; multiple element forming sections that are provided in the active region; a semiconductor element that is formed in each of the element forming sections; and a channel stopper that is provided in the active region to insulate the element forming sections from each other. The channel stopper comprises: a fin that protrudes between grooves provided in the element-isolation insulating film and on both sides of the active region; a dummy-gate insulating film that covers the fin; and a dummy gate electrode that straddles the fin.

### BACKGROUND OF THE INVENTION

1. Field of the Invention

The present invention relates to a semiconductor device and a method of manufacturing the same.

Priority is claimed on Japanese Patent Application No 2007-263248, filed Oct. 9, 2007, the content of which is incorporated herein by reference.

2. Description of the Related Art

In semiconductor devices, an element isolation technique using an STI (shallow trench isolation) method has been known. Hereinafter, a conventional semiconductor device including an STI element isolation structure is explained with reference to accompanying drawings.

FIG. 22 is a plane view showing an example of a memory cell of DRAM (Dynamic Random Access Memory) as a conventional semiconductor device. As shown in FIG. 22, STI element isolation regions 151 made of an element-isolation insulating film embedded on a semiconductor substrate and active regions 152 surrounded by the element isolation regions 151 are formed in the conventional DRAM memory cell. The active regions 152 are regularly arranged on the semiconductor substrate.

Gate electrodes 153, 154, and 155 are formed crossing over the multiple active regions 152. The gate electrodes 153 to 155 serve as word lines of the DRAM. With respect to one active region 152, two gate electrodes 153 and 154 are formed crossing over the active region 152. Source/drain diffusion layers 156 to 158 (hereinafter, “SD diffusion layers”) are formed on both sides of each of the gate electrodes 153 and 154.

For example, SD diffusion layers 156 and 157 are formed on both sides of the gate electrode 153, and the gate electrode 153 and the SD diffusion layers 156 and 157 form an MOS transistor. Similarly, SD diffusion layers 157 and 158 are formed on both sides of the gate electrode 154, and the gate electrode 154 and the SD diffusion layers 157 and 158 form another MOS transistor. The SD diffusion layer 157 between the gate electrodes 153 and 154 is shared by the two transistors.

SD contact plugs 156a, 157a, and 158a are formed on the SD diffusion layers 156 to 158, and the SD diffusion layers 156 to 158 are connected to conductors on an upper layer through the contact plugs 156a to 158a. Usually, capacitors are formed above the contact plugs 156a and 158a, and a bit line is connected to a portion above the SD contact plug 157a.

The active region 152 has a width W in the short-side direction and a width L in the long-side direction. The adjacent active regions 152 in the short-side direction are separated from each other by a width S1 and arranged at a pitch P. The adjacent active regions 152 in the long-side direction are separated from each other by a width S2 (see Japanese Unexamined Patent Application, First Publication No. 2003-68877).

When further miniaturization is pursued and the interval S1 between the active regions 152 narrows in the conventional DRAM memory cell, it becomes difficult to embed the element-isolation insulating film. The failure to embed the element-isolation insulating film causes various defects such as a short circuit of adjacent gate electrodes. If the interval S1 is widened to prevent the defects, the width W of the active region 152 necessarily decreases. The active region 152 is formed by covering an area to be the active region with a mask made of photoresist, dry etching the semiconductor substrate to pattern the active region, and embedding the element-isolation insulating film. However, the width W of the active region 152 decreases as explained above, and the width L in the long-side direction at the end portions of the active region 152 decreases due to the characteristics of lithography when a mask pattern is formed by the lithography. The end portions of the active region further decrease by the dry etching afterward. As a result, the areas of both ends of the active region 152 deviated from the gate electrodes 153 and 154 in the width direction decrease as shown in FIG. 23. Accordingly, the areas of the SD diffusion layers 156 and 158 extremely decrease, the contact areas of the SD contact plugs 156a and 158a and the SD diffusion layers 156 and 158 decrease, and the contact resistance increases, thereby causing a circuit operation delay.

### SUMMARY

In one embodiment, there is provided a semiconductor device that may include: an active region that is insulated by an element-isolation insulating film embedded on a semiconductor substrate; multiple element forming sections that are provided in the active region; a semiconductor element that is formed in each of the element forming sections; and a channel stopper that is provided in the active region to insulate the element forming sections from each other. The channel stopper includes: a fin that protrudes between grooves provided in the element-isolation insulating film and on both sides of the active region; a dummy-gate insulating film that covers the fin; and a dummy gate electrode that straddles the fin.

In another embodiment, there is provided a method of manufacturing a semiconductor device including multiple element forming sections provided in an active region on a semiconductor substrate, a semiconductor element formed in each of the element forming sections, and a channel stopper provided in the active region to insulate the element forming sections from each other. The method may include: embedding an element-isolation insulating film on the semiconductor substrate to form the active region; providing grooves in the element-isolation insulating film and at least on both sides of a portion to be the channel stopper to form a fin protruding between the grooves; forming a dummy-gate insulating film that covers the fin; and forming a dummy gate electrode so as to straddle the fin through the dummy-gate insulating film.

According to the semiconductor device and the method of manufacturing the semiconductor device, the element forming section and the channel stopper are provided in the active region. Thereby, the active regions need not be minutely insulated from one another by the element isolation insulating film. As a result, the areas of the source drain regions do not decrease even if the width of the active region is narrowed, thereby preventing an increase in the contact resistance of the contact plugs.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic plan view showing a semiconductor device according to a first embodiment of the present invention;

FIG. 2 is a schematic perspective view showing a main part of the semiconductor device according to the first embodiment of the present invention;

FIG. 3 is a schematic cross-sectional view showing the semiconductor device according to the first embodiment of the present invention, and FIG. 3 at (a) is a cross-sectional view along an A-A′ line shown in FIG. 1, FIG. 3A is a cross-sectional view along a C-C′ line shown in FIG. 1, FIG. 3C is a cross-sectional view along a D-D′ line shown in FIG. 1, and FIG. 3D is a cross-sectional view along an E-E′ line shown in FIG. 1;

FIG. 4 shows a method of manufacturing the semiconductor device shown in FIGS. 1 to 3 and a process of forming an active region;

FIG. 5 shows the method of manufacturing the semiconductor device shown in FIGS. 1 to 3 and the process of forming the active region;

FIG. 6 shows the method of manufacturing the semiconductor device shown in FIGS. 1 to 3 and a process of forming a fin;

FIG. 7 shows the method of manufacturing the semiconductor device shown in FIGS. 1 to 3 and the process of forming the fin;

FIG. 8 shows the method of manufacturing the semiconductor device shown in FIGS. 1 to 3 and the process of forming the fin;

FIG. 9 shows the method of manufacturing the semiconductor device shown in FIGS. 1 to 3 and the process of forming the fin;

FIG. 10 shows the method of manufacturing the semiconductor device shown in FIGS. 1 to 3 and a process of forming a gate insulating film;

FIG. 11 shows the method of manufacturing the semiconductor device shown in FIGS. 1 to 3 and a process of forming a gate electrode and a dummy gate electrode;

FIG. 12 shows the method of manufacturing the semiconductor device shown in FIGS. 1 to 3 and the process of forming the gate electrode and the dummy gate electrode;

FIG. 13 shows the method of manufacturing the semiconductor device shown in FIGS. 1 to 3 and the process of forming the gate electrode and the dummy gate electrode;

FIG. 14 shows the method of manufacturing the semiconductor device shown in FIGS. 1 to 3 and the process of forming the gate electrode and the dummy gate electrode;

FIG. 15 shows the method of manufacturing the semiconductor device shown in FIGS. 1 to 3 and the process of forming the gate electrode and the dummy gate electrode;

FIG. 16 shows the method of manufacturing the semiconductor device shown in FIGS. 1 to 3 and a process of forming a source drain region;

FIG. 17 shows the method of manufacturing the semiconductor device shown in FIGS. 1 to 3 and the process of forming and activating the source drain region;

FIG. 18 shows the method of manufacturing the semiconductor device shown in FIGS. 1 to 3 and a process of forming a contact plug;

FIG. 19 shows the method of manufacturing the semiconductor device shown in FIGS. 1 to 3 and a process of forming a capacitor and a wiring;

FIG. 20 is a schematic cross-sectional view showing a semiconductor device according to a second embodiment of the present invention, and FIG. 20A is a cross-sectional view along the A-A′ line shown in FIG. 1, FIG. 20B is a cross-sectional view along the C-C′ line shown in FIG. 1, FIG. 20C is a cross-sectional view along the D-D′ line shown in FIG. 1, and FIG. 20D is a cross-sectional view along the E-E′ line shown in FIG. 1;

FIG. 21 is a schematic cross-sectional view showing a semiconductor device according to a third embodiment of the present invention, and FIG. 21A is a cross-sectional view along the A-A′ line shown in FIG. 1, FIG. 21B is a cross-sectional view along the C-C′ line shown in FIG. 1, FIG. 21C is a cross-sectional view along the D-D′ line shown in FIG. 1, and FIG. 21D is a cross-sectional view along the E-E′ line shown in FIG. 1;

FIG. 22 is a schematic plan view showing a conventional semiconductor device; and

FIG. 23 is a schematic plan view showing a main part of the conventional semiconductor device.

### DETAILED DESCRIPTION OF THE PREFERRED EMBODIMENTS

The invention will be now described herein with reference to illustrative embodiments. A case where a semiconductor device is applied to a DRAM memory cell is explained in the embodiments.

The accompanying drawings explain a semiconductor device in the embodiments, and the size, the thickness, and the like of each illustrated portion might be different from those of each portion of an actual semiconductor device.

Those skilled in the art will recognize that many alternative embodiments can be accomplished using the teaching of the present invention and that the invention is not limited to the embodiments illustrated herein for explanatory purpose.

### First Embodiment

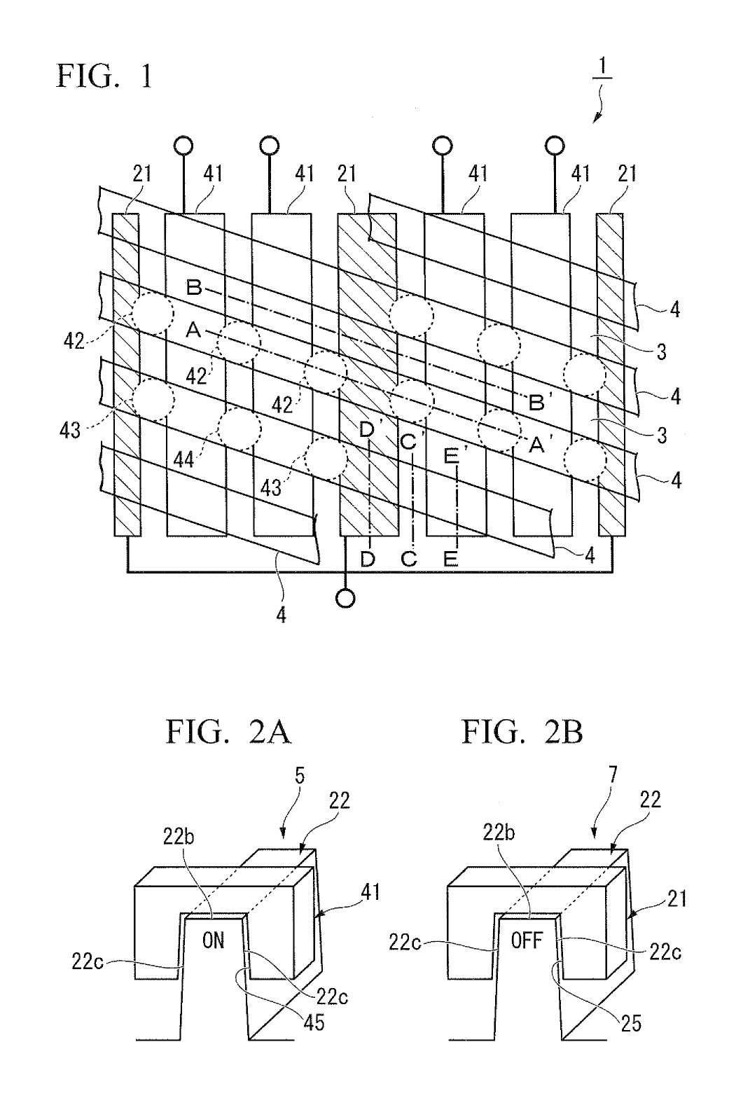

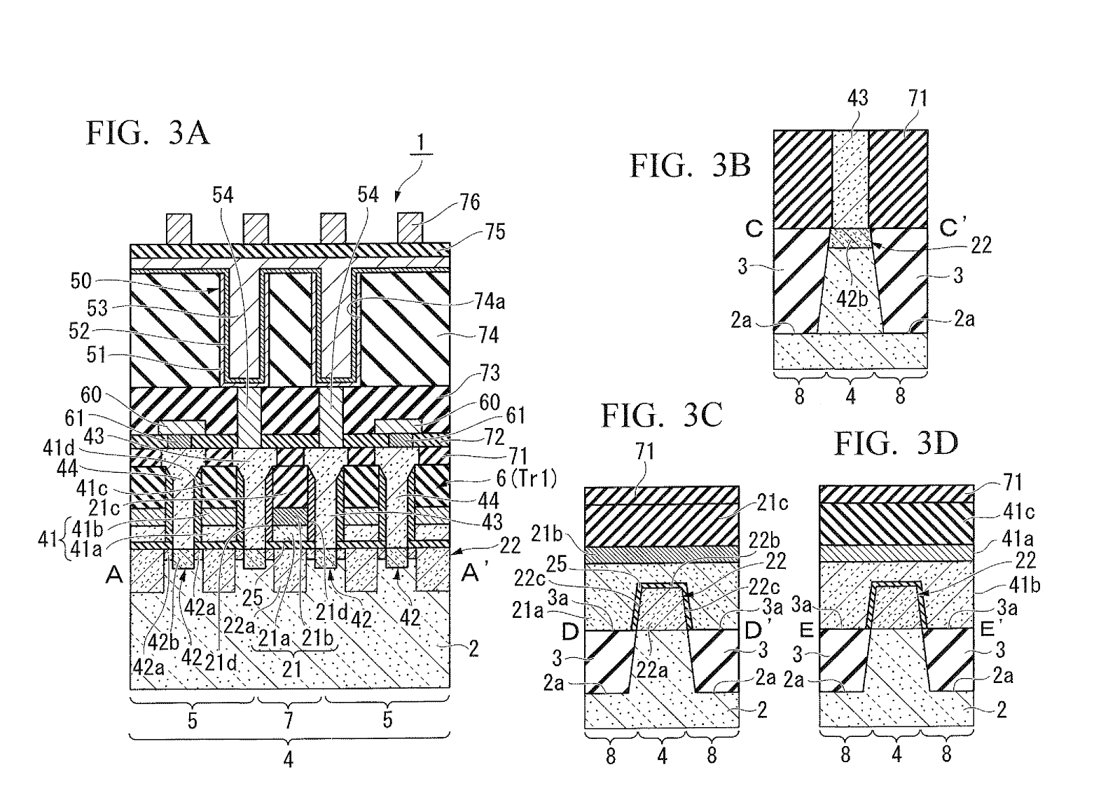

A semiconductor device according to a first embodiment is explained with reference to FIG. 1. FIG. 1 is a schematic plan view showing the semiconductor device according to the first embodiment. FIG. 2 is a schematic perspective view showing a main part of the semiconductor device according to the first embodiment. FIG. 3 is a schematic cross-sectional view showing the semiconductor device according to the first embodiment, and FIG. 3A is a cross-sectional view along an A-A′ line shown in FIG. 1, FIG. 3B is a cross-sectional view along a C-C′ line shown in FIG. 1, FIG. 3C is a cross-sectional view along a D-D′ line shown in FIG. 1, and FIG. 3D is a cross-sectional view along an E-E line shown in FIG. 1.

A semiconductor device 1 shown in FIGS. 1 to 3 includes active regions 4 insulated from each another by an element-isolation insulating film 3 embedded on a semiconductor substrate 2, multiple element forming sections 5 provided in each active region 4, a semiconductor element 6 formed in each element forming section 5, and a channel stopper 7 provided in each active region 4 for insulating element forming sections 5 from each other. The semiconductor device 1 according to the first embodiment is an example where a fin MOS transistor is used as the semiconductor element 6. Not only the fin MOS transistor but also a planar or a trench MOS transistor may be used, which will be explained later.

The semiconductor substrate 2 is made of a substrate including an impurity at a given concentration, such as a silicon substrate. The semiconductor substrate 2 may be a substrate, at least a surface of which is made of silicon.

As shown in FIGS. 1 and 3, the element-isolation insulating film 3 made of a silicon oxide film is embedded on a trench 2a provided on the semiconductor substrate 2, and the region of the element-isolation insulating film 3 is regarded as an STI element isolation region 8. Additionally, multiple active regions 4, each of which is a part of the semiconductor substrate 2 and which are insulated from one another by the STI element isolation region 8 are formed on the semiconductor substrate 2.

The active regions 4 are compartmentalized such that the planar view thereof is in a zonal manner as shown in FIG. 1. Silicon constituting the semiconductor substrate 2 is exposed on the active region 4. The element-isolation insulating film 3 is located on both sides of each active region 4 in the width direction.

As shown in FIG. 1, the semiconductor device 1 includes a dummy gate electrode 21 and a gate electrode 41. The dummy gate electrode 21 and the gate electrode 41 cross over the multiple active regions 4. With respect to one active region 4, two gate electrodes 41 and one dummy gate electrode 21 are alternately arranged in parallel and cross over the active region 4. The dummy gate electrode 21 is arranged so as to pass through the channel stopper 7 in the active region 4. On the other hand, the gate electrode 41 is arranged so as to pass through the element forming section 5 in the active region 4. The gate electrode 41 serves as a word line of the DRAM and is connected to a non-depicted gate-voltage drive circuit. On the other hand, the dummy gate electrode 21 is connected to, for example, ground power and supplied a control potential different from that supplied to the gate electrode 41.

As shown in FIG. 1, source drain regions 42 are formed on both sides of each gate electrode 41 and in the active region 4. One gate electrode 41 and two source drain regions 42 on both sides thereof form one MOS transistor. The source drain region 42 between the two gate electrodes 41 is shared with two MOS transistors.

Contact plugs 43 and 44 are formed on the source drain regions 42, and the source drain regions 42 are connected to conductors on an upper layer through the contact plugs 43 and 44. Usually, a capacitor 50 is formed above the contact plug 43, and a bit line 60 is connected to a portion above the contact plug 44.

Hereinafter, the channel stopper 7 is explained. As shown in FIGS. 2B and 3, the channel stopper 7 includes a fin 22 provided in the active region 4, a dummy-gate insulating film 25 covering the fin 22, and a dummy gate electrode 21 straddling the fin 22.

Grooves 3a are provided in the element-isolation insulating films 3 on both sides of the active region 4, and thereby form the fin 22 protruding therebetween. The fin 22 is formed not only at the channel stopper 7 in the active region 4 but also at the element forming section 5 along the active region 4 in the longitudinal direction. The well region 22a constituting the channel region is formed in the fin 22. The well region 22a is formed by injecting a p-type dopant such as boron into the fin 22, and the p-type dopant is diffused over the entire portion protruding from the groove 3a of the element-isolation insulating film 3. The amount of the dopant injected into the well region 22a is suppressed to the extent that leaks at the junction do not increase significantly.

The dummy-gate insulating film 25 is formed on the fin 22. The dummy-gate insulating film 25 is formed on an upper surface 22b of the fin 22 and side surfaces 22c exposed by forming the grooves 3a. The dummy-gate insulating film 25 may be a silicon oxide film, a silicon oxynitride film, an Hf dielectric film respectively formed by performing a thermal oxidation process, a thermal oxynitridation process, and the CVD for the surface of the fin 22.

A part of the dummy gate electrode 21 is embedded on the grooves 3 a provided in the element-isolation insulating film 3. Thereby, the dummy gate electrode 21 straddles the fin 22.

The dummy gate electrode 21 is embedded on the grooves 3a and includes a polysilicon layer 21a covering the upper surface 22b of the fin 22 and a metal layer 21b layered on the polysilicon layer 21a. The p-type dopant, such as boron, is doped in the polysilicon layer 21a at a high concentration. As a result, the polysilicon layer 21a of the dummy gate electrode 21 is a P⁺ semiconductor. An insulating layer 21c made of, for example, a silicon nitride film is layered on the metal layer 21b, and sidewall films 21d made of a silicon nitride film is formed on both sides of the polysilicon layer 21a and the metal layer 21b.

The polysilicon layer 21a is embedded on the grooves 3a, and thereby arranged so as to oppose the upper surface 22b and side surfaces 22c of the fin 22 through the dummy-gate insulating film 25. As a result, the channel stopper 7 has a fin-type channel structure in which the dummy gate electrode 21 straddles the fin 22. The polysilicon layer 21a is arranged so as to oppose the upper surface 22b and the side surfaces 22c of the fin 22, and thereby preventing current from leaking from the side surfaces 22c. Therefore, the on-state suppression effect is reflected on the upper surface 22b and two side surfaces 22c, and element isolation can certainly be achieved in an off state.

Hereinafter, the configuration of an n-type fin MOS transistor Tr₁ formed in the element forming section 5 is explained. As shown in FIGS. 2A and 3, the n-type fin MOS transistor Tr₁ (hereinafter, “transistor Tr₁”) includes the fin 22 provided in the active region 4, a gate insulating film 45 covering the fin 22, and a gate electrode 41 straddling the fin 22 through the gate insulating film 45.

The fin 22 in the element forming section 5 is the fin 22 formed at the channel stopper 7 and extending to the element forming section 5 in the longitudinal direction of the active region 4. The well region 22a constituting the channel region is similarly provided in the fin 22 at the element forming section 5. The amount of the dopant injected into the well region 22a is suppressed to the extent that leaks at the junction do not increase significantly.

The gate insulating film 45 is formed on the fin 22. The gate insulating film 45 is formed on the upper surface 22b of the fin 22 and the side surfaces 22c exposed by forming the grooves 3a. The gate insulating film 45 may be a silicon oxide film, a silicon oxynitride film, an Hf dielectric film respectively formed by performing a thermal oxidation process, a thermal oxynitridation process, and the CVD for the surface of the fin 22. Preferably, the material of the gate insulating film 45 is the same as that of the dummy-gate insulating film 25.

A part of the gate electrode 41 is embedded on the groove 3a provided in the element-isolation insulating film 3, and thereby straddles the fin 22.

The gate electrode 41 is embedded on the groove 3a and includes a polysilicon layer 41a covering the upper surface 22b of the fin 22 and a metal layer 41b layered on the polysilicon layer 41a. An n-type dopant such as phosphorus is doped in the polysilicon layer 41a. An insulating layer 41c made of for example, a silicon nitride film is layered on the metal layer 41b, and sidewall films 41d made of, for example, a silicon nitride film is formed on both sides of the polysilicon layer 41a and the metal layer 41b.

The polysilicon layer 41a is embedded on the groove 3a, and thereby arranged so as to oppose the upper surface 22b and the side surfaces 22c of the fin 22 through the gate insulating film 45. As a result, the fin-type channel structure in which the gate electrode 41 straddles the fin 22 is provided. The channel length is extended due to this structure, and therefore, the short channel effect can be prevented even in the case of higher integration of MOS transistors.

The source drain regions 42 are formed on the fin 22 and on both sides of the gate electrode 41. The source drain region 42 includes an extension region 42a formed under the sidewall film 41d and a contact region 42b formed at a position not overlapping the sidewall film 41d. Thus, the LDD structure is formed in the transistor Tr₁ of the first embodiment.

In the semiconductor device 1, a first inter-layer insulating film 71 and a second inter-layer insulating film 72 are sequentially layered so as to cover the dummy gate electrode 21, a gate electrode 41, and a semiconductor substrate 2, and a bit line 60 is formed on the second inter-layer insulating film 72. The contact plugs 43 and 44 are formed in the first inter-layer insulating film 71. A bit-line contact plug 61 connecting the contact plug 44 and the bit line 60 is embedded in the second inter-layer insulating film 72.

Third and fourth inter-layer insulating films 73 and 74 are layered so as to cover the second inter-layer insulating film 72 and the bit line 60. A cylinder hole 74a is provided in the fourth inter-layer insulating film 74, and a capacitor 50 including a lower electrode layer 51, a dielectric layer 52, and an upper electrode layer 53 is formed in the cylinder hole 74a. A capacitor contact plug 54 connecting the contact plug 43 and the lower electrode layer 51 of the capacitor 50 is formed in the third inter-layer insulating film 73.

A fifth inter-layer insulating film 75 is layered on the upper electrode layer 53, and a wiring layer 76 is formed on the fifth inter-layer insulating film 75.

As explained above, the source drain regions 42 of the transistors Tr1 are connected to the capacitor and the bit line, and the gate electrode 41 is connected to the word line, thereby forming the DRAM memory cell.

In the semiconductor device 1, each gate electrode 41 is connected to a non-depicted gate-voltage drive-circuit. On the other hand, the dummy gate electrode 21 is connected to another power circuit capable of applying a control potential different from the gate voltage.

When the transistor Tr₁ is turned off, a negative potential has to be supplied to the gate electrode 41 through the gate drive circuit to suppress the off current to the degree that the off current is negligible since the amount of the dopant injected into the well region 22a of the fin 22 is suppressed to the degree that leaks at the junction do not increase significantly. The period of this state is sufficiently long for a circuit operation, and thereby the unignorable power is consumed. On the other hand, the dummy gate electrode 21 has the P⁺ polysilicon gate structure with respect to the n-type MOS transistor. Therefore, a threshold voltage of the dummy gate electrode 21 is relatively high due to the work function difference, for example, +1.0 V compared with that of the transistor Tr₁ including the gate electrode 41. As a result, only the ground potential is enough to prevent the current from flowing. Therefore, the circuit power is hardly consumed.

Hereinafter, a method of manufacturing the semiconductor device 1 is explained.

A method of manufacturing the semiconductor device according to the first embodiment includes an active-region forming process of forming the active regions 4, a fin forming process of forming the fin 22, an insulating-film forming process of forming the dummy-gate insulating film 25, and a dummy-gate-electrode forming process of forming the dummy gate electrode 21.

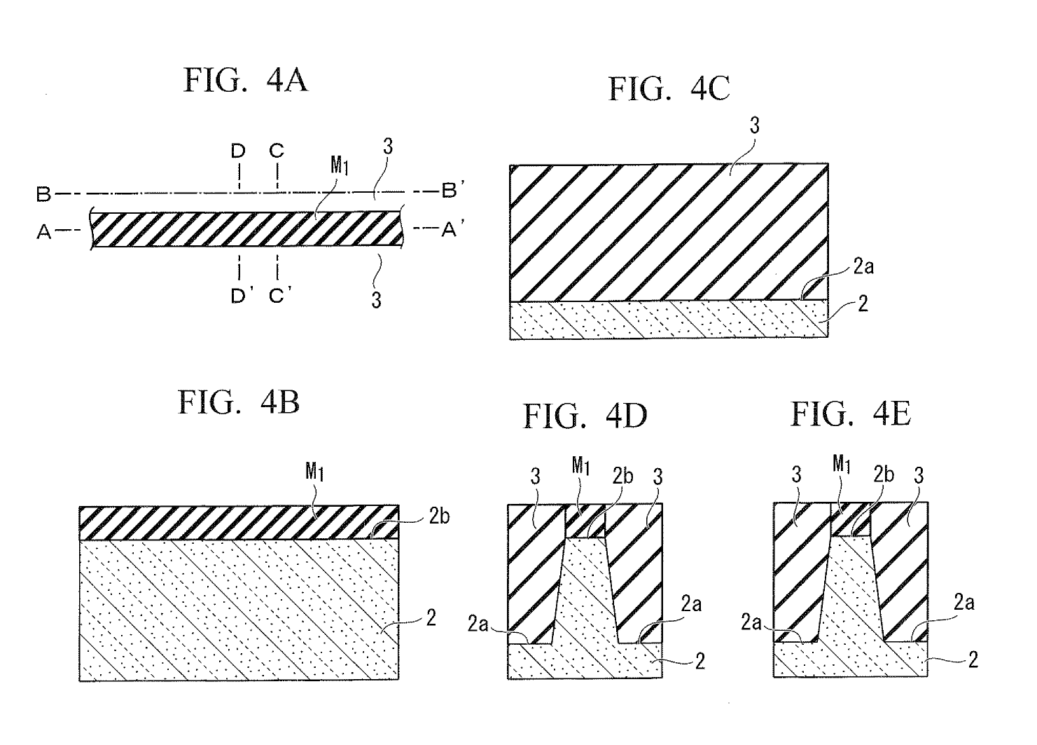

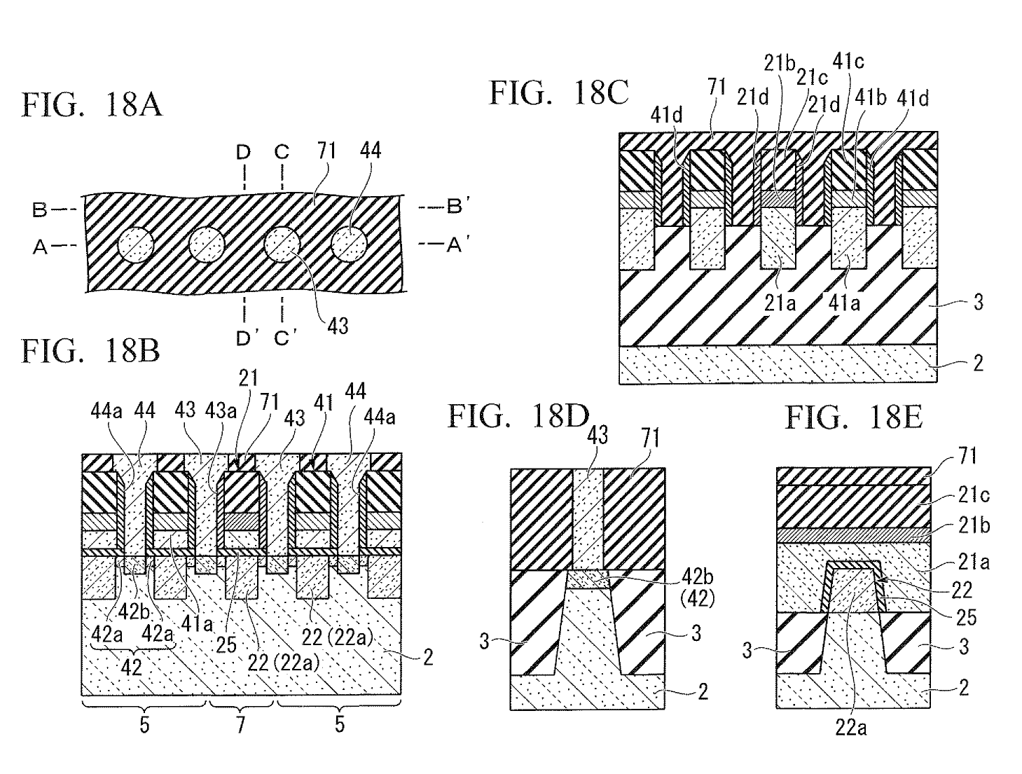

Hereinafter, each process is explained with reference to FIGS. 4 to 21. FIGS. 4A to 21A are plan views showing the semiconductor substrate, FIGS. 4B to 21B are cross-sectional views along A-A′ lines shown in FIGS. 4A to 21A, FIGS. 4C to 21C are cross-sectional views along B-B′ lines shown in FIGS. 4A to 21A, FIGS. 4D to 21D are cross-sectional views along D-D′ lines shown in FIGS. 4A to 21A, and FIGS. 4E to 21E are cross-sectional views along C-C′ lines shown in FIGS. 4A to 21A.

In the active-region forming process, the active regions 4 and the STI element isolation regions 8 are formed at the same time by embedding the element-isolation insulating film 3 on the semiconductor substrate 2.

In other words, as shown in FIG. 4, a mask layer M₁ made of a silicon nitride film is formed on the entire surface 2b of the semiconductor substrate 2. The shape of the active regions 4 is determined according to the shape of the mask layer M₁. The trench 2a of 250 nm in depth is formed by dry etching the semiconductor substrate 2 with the mask layer M₁ as a mask. The element-isolation insulating film 3 made of, for example, a silicon oxide is embedded on the trench 2a, and the element-isolation insulating film 3 is planarized by the CMP until the mask layer M₁ is exposed.

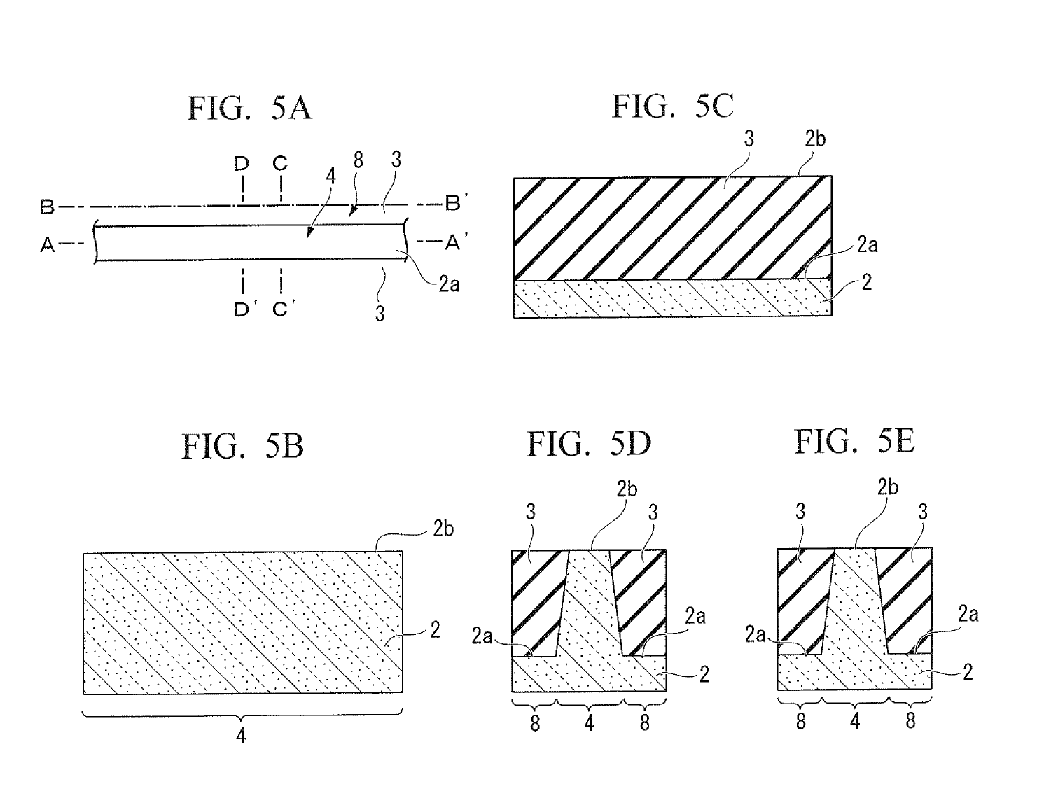

As shown in FIG. 5, etching with more selectivity than that to the silicon nitride film (mask layer M₁) is performed for the element-isolation insulating film 3, and the element-isolation insulating film 3 is etched back so that the surface of the element-isolation insulating film 3 becomes identical to the surface 2b of the semiconductor substrate 2. Then, the mask layer M₁ is removed. In this manner, the active regions 4 and the STI element isolation regions 8 are formed at the same time.

In the fin forming process, grooves 3a are provided at least on both sides of the portion to be the channel stopper 7 in the active region 4, and thereby forming the fin 22 protruding between the grooves 3a.

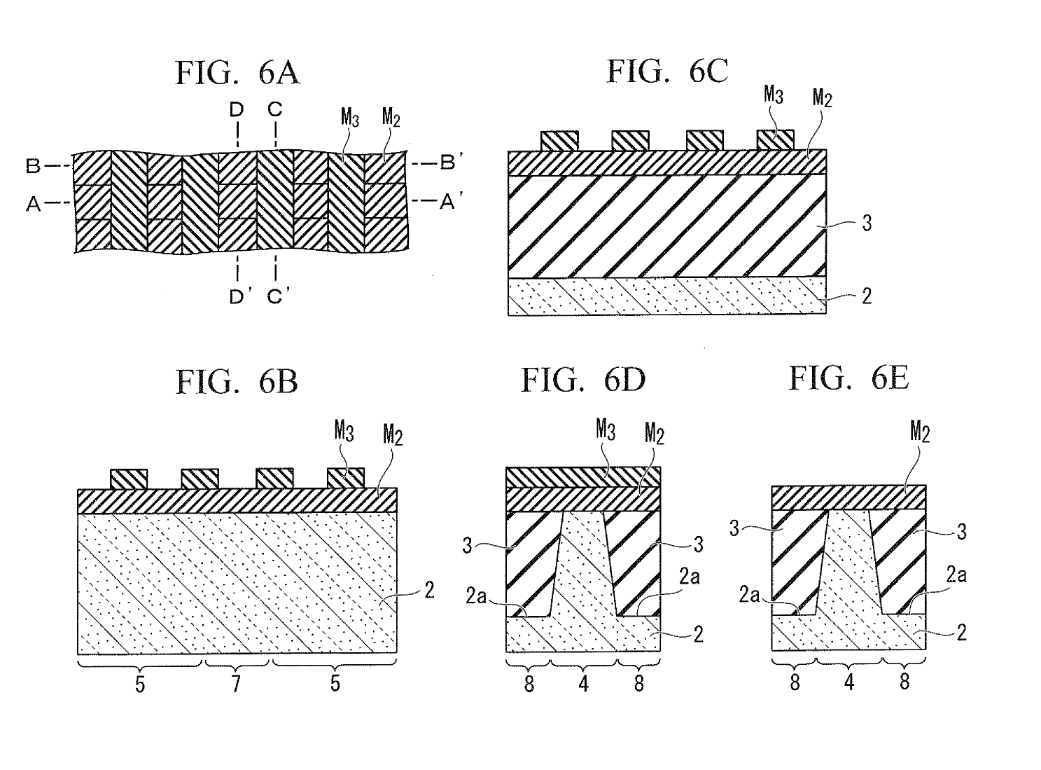

In other words, as shown in FIG. 6, a silicon nitride film M₂ is formed on the entire surface of the semiconductor substrate 2, a photoresist layer M₃ is formed on the silicon nitride film M₂, and the photoresist layer M₃ is patterned. The photoresist layer M₃ is patterned in a zonal manner in the direction crossing the longitudinal direction of the active regions 4.

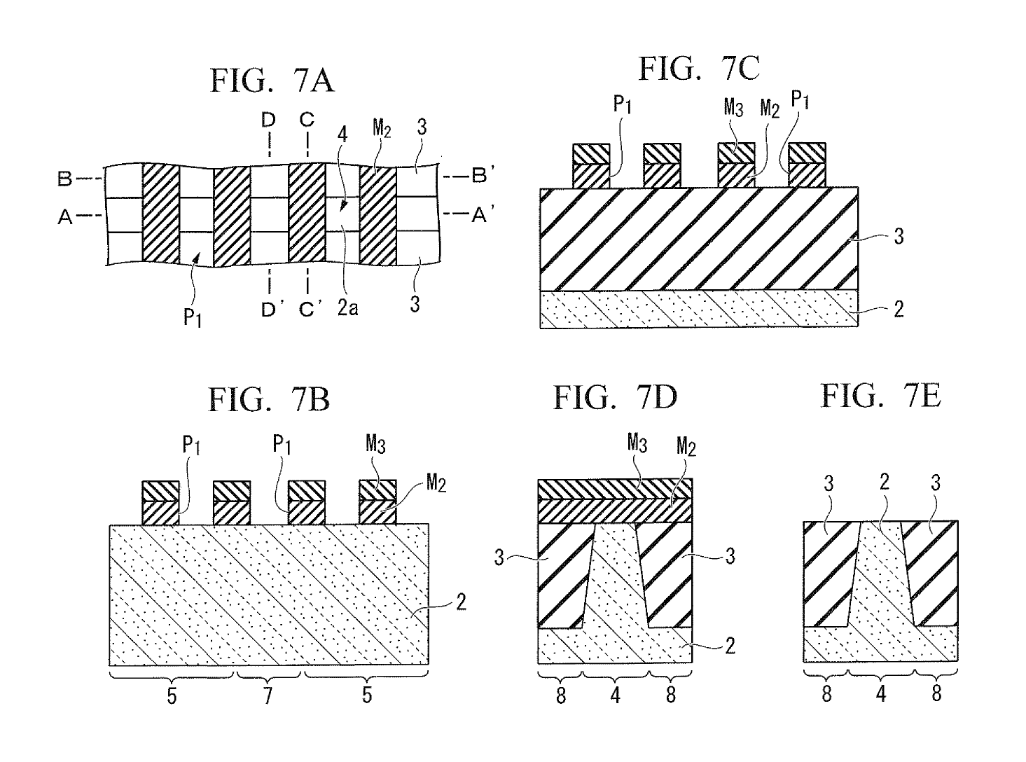

As shown in FIG. 7, the silicon nitride film M₂ is dry etched and patterned with the photoresist layer M₃ as a mask. As a result, a groove pattern P₁ is formed in the silicon nitride layer M₂. Preferably, the width of the groove pattern P₁ is 50 nm, for example.

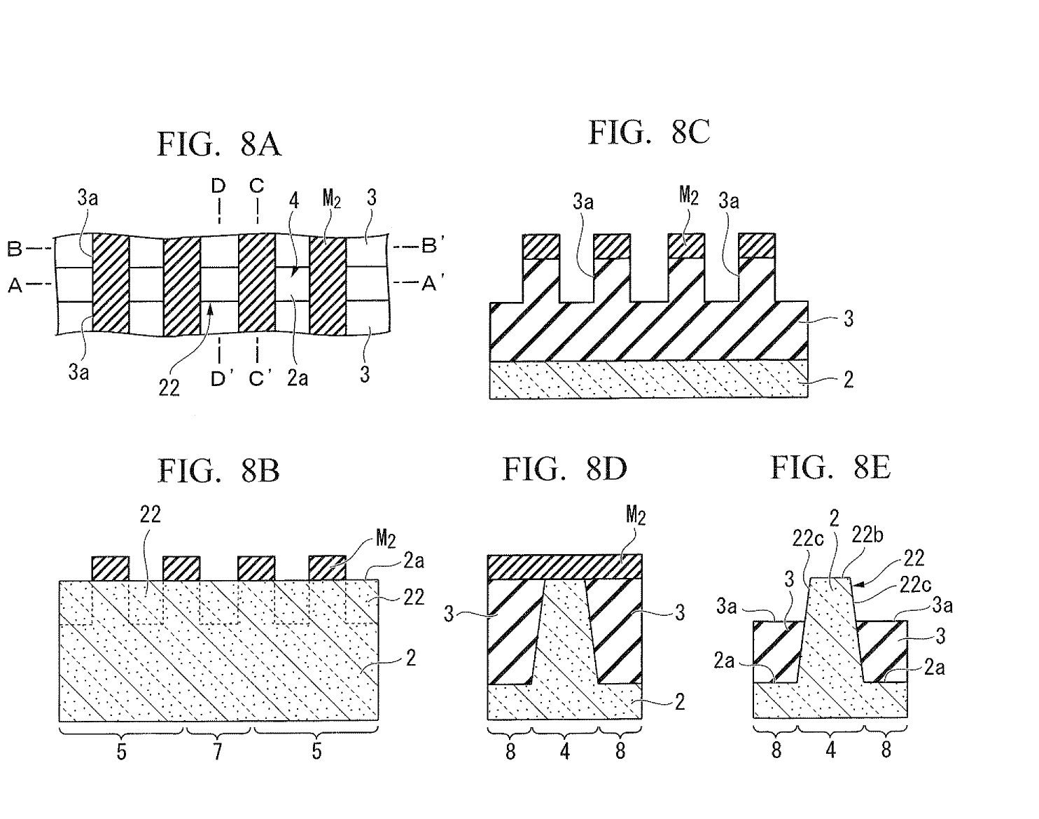

As shown in FIG. 8, the element-isolation insulating film 3 is dry etched with the silicon nitride film M₂ including the groove pattern P₁ as a mask. This dry etching is performed with the selectivity to the silicon oxide is higher than that to the silicon. As a result, the grooves 3a are formed on the element-isolation insulating film 3 located on both sides of the active region 4 in the widthwise direction. The grooves 3a are formed along a direction crossing the longitudinal direction of the active region 4. Preferably, the depth of the groove 3a is 100 nm and the width thereof is 50 nm, for example. The photoresist layer M₃ is etched by the dry etching at this time.

The grooves 3a are provided on the element-isolation insulating films 3 on both sides of the active region 4, and thereby form the fin 22 protruding between the grooves 3a and in the active region 4. The fin 22 includes the upper surface 22b and the side surfaces 22c exposed by the grooves 3a being formed. Additionally, the fin 22 is formed not only at the channel stopper 7 in the active region 4, but also at the element forming section 5.

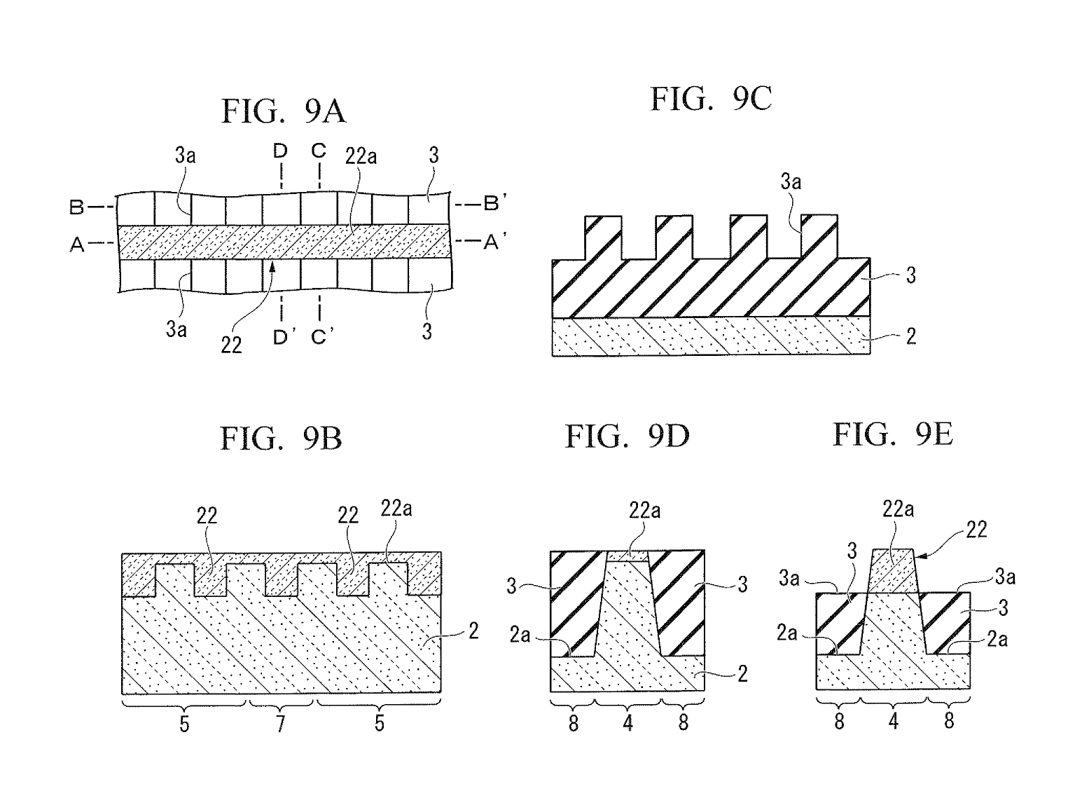

As shown in FIG. 9, the silicon nitride film M₂ is removed, and then a p-type dopant, such as boron, is ion-injected into the active region 4. The injection amount need be suppressed to the degree that leaks at the junction do not increase significantly. Preferably, the ion injection is performed under the condition that an acceleration energy is 10 keV and a dose amount is 1×10¹³/cm². As a result, the well region 22a is formed in the active region 4 as shown in FIG. 9. The well region 22a is formed to be deeper at the fin 22 than that at another portion.

In the insulating film forming process, an insulating film 80 covering the fin 22 is formed.

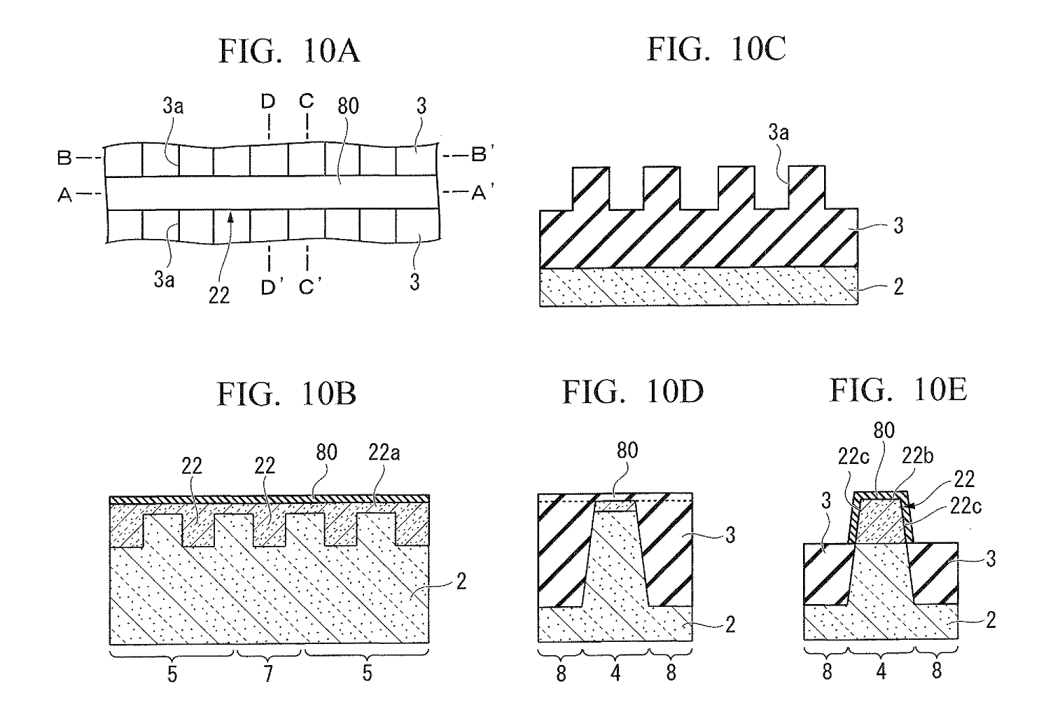

More specifically, the insulating film 80 is formed on the surface of the fin 22 using thermal oxidation as shown in FIG. 10. As a result, the upper surface 22b and the side surfaces 22c of the fin 22 are covered by the insulating film 80. The insulating film 80 is patterned with the dummy gate electrode 21 and the gate electrode 41 at the following process, and becomes the dummy-gate insulating film 25 and the gate insulating film 45.

In the dummy-gate electrode forming process, the dummy gate electrode is formed.

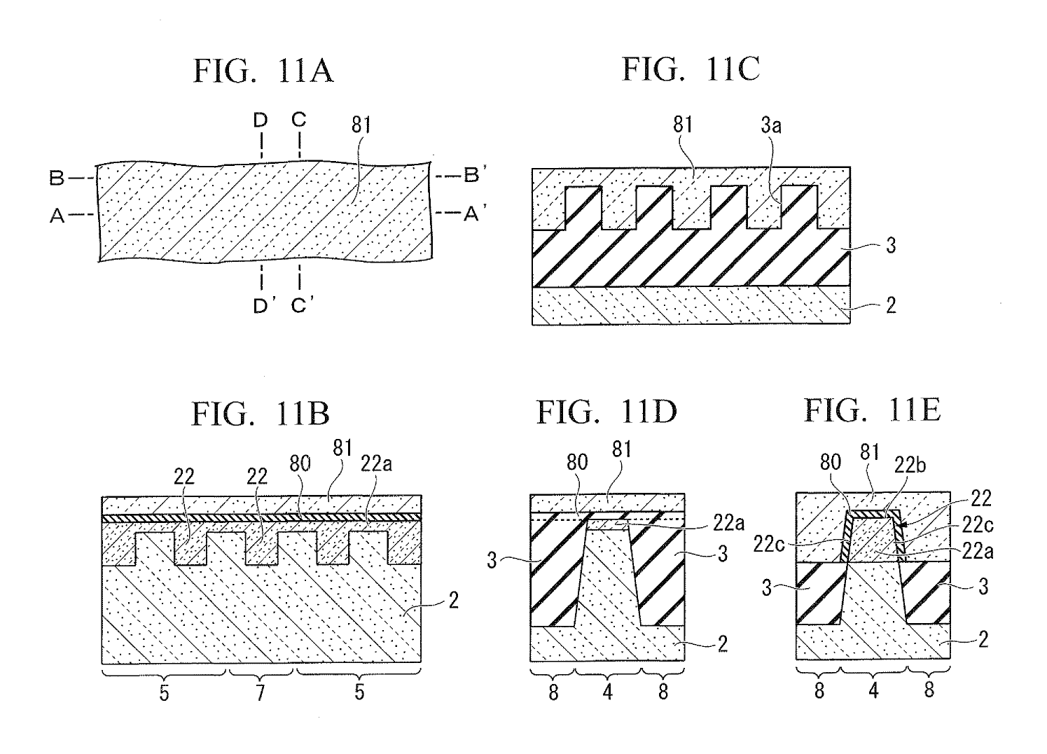

As shown in FIG. 11, a polysilicon film (silicon film) 81 with a thickness of, for example, 100 nm at the maximum is formed so as to cover the grooves 3a and the insulating film 80 using the CVD. An amorphous silicon film in lieu of the polysilicon film 81 may be formed. The amorphous silicon film finally becomes a polysilicon film by a thermal treatment at the following process.

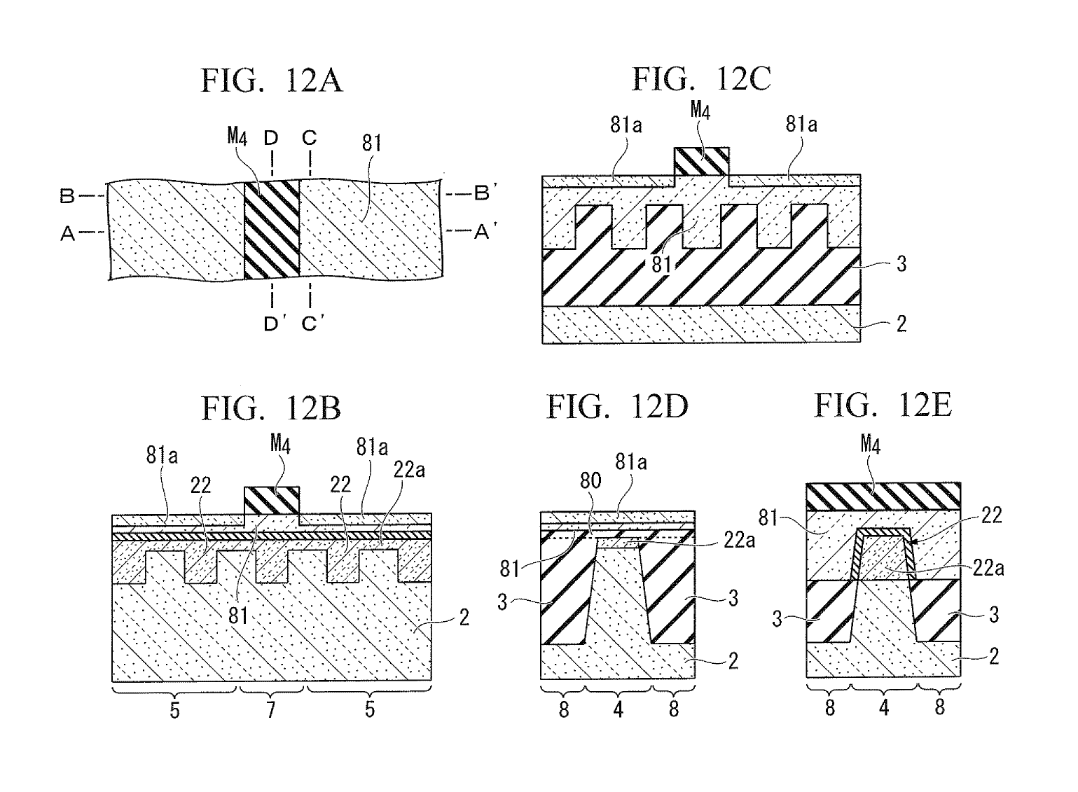

As shown in FIG. 12, a mask M₄ made of photoresist is formed on the polysilicon film 81. The mask M₄ is formed in a zonal manner so as to cross over the portion to be the channel stopper 7 in the active region 4.

As shown in FIG. 12, an N-type dopant, such as phosphorus, is ion-injected onto the portion on the polysilicon film 81 that is not covered by the mask M₄. Preferably, the ion injection is performed under the condition that an acceleration energy is 8 keV and a dose amount is 1×10¹⁶/cm². As a result, the N doped portion 81a is formed on the polysilicon film 81 as shown in FIG. 12. The N doped portion 81a is formed at least above the element forming section 5 in the active region 4. In the N doped portion 81a, the injected N-type dopant is unevenly distributed in the vicinity of the surface of the polysilicon film 81.

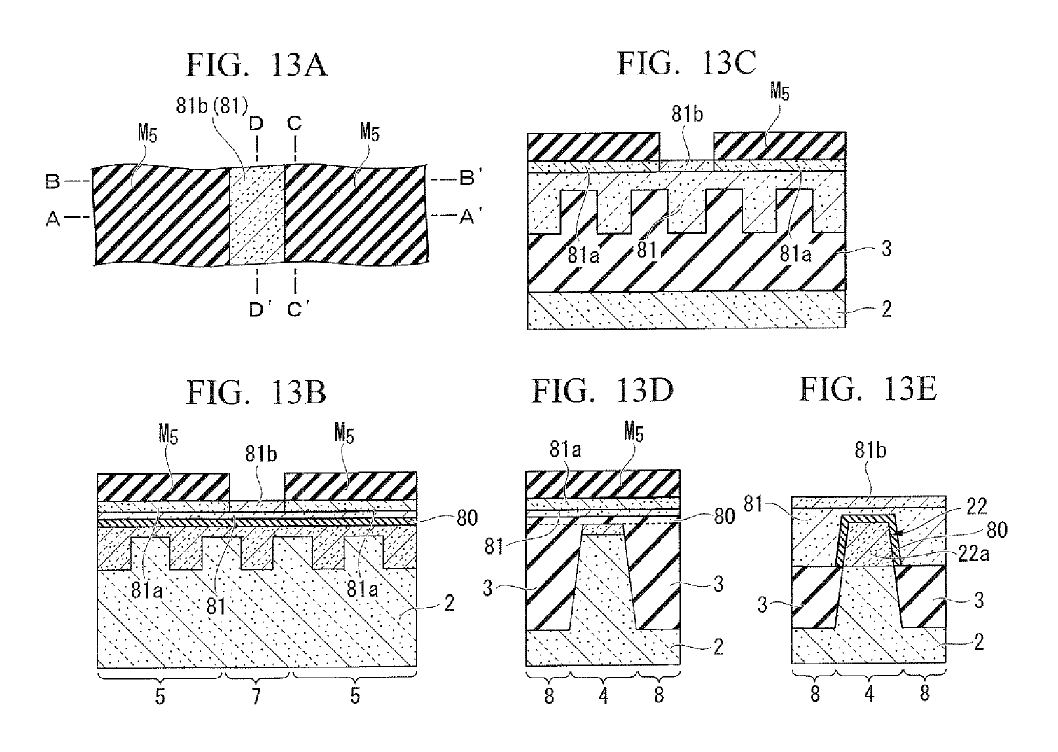

As shown in FIG. 13, a mask layer M₅ made of photoresist is formed on the polysilicon film 81 with the mask layer M₄ removed. The mask layer M₅ is formed in a zonal manner so as to cross over the portion to be the element forming section 5 in the active region 4.

As shown in FIG. 13, a P-type dopant such as boron is ion-injected onto the portion on the polysilicon film 81 that is not covered by the mask M₅. Preferably, the ion injection is performed under the condition that an acceleration energy is 4 keV and a dose amount is 1×10¹⁶/cm². As a result, a P doped portion 81b is formed in the polysilicon film 81 as shown in FIG. 13.

The P doped portion 81b is formed at least above the channel stopper 7 in the active region 4. In the P doped portion 81b, the injected P-type dopant is unevenly distributed in the vicinity of the surface of the polysilicon film 81.

The order of forming the N doped portion 81a and the P doped portion 81b is not limited hereto, and the N doped portion 81a may be formed after the P doped portion b is formed.

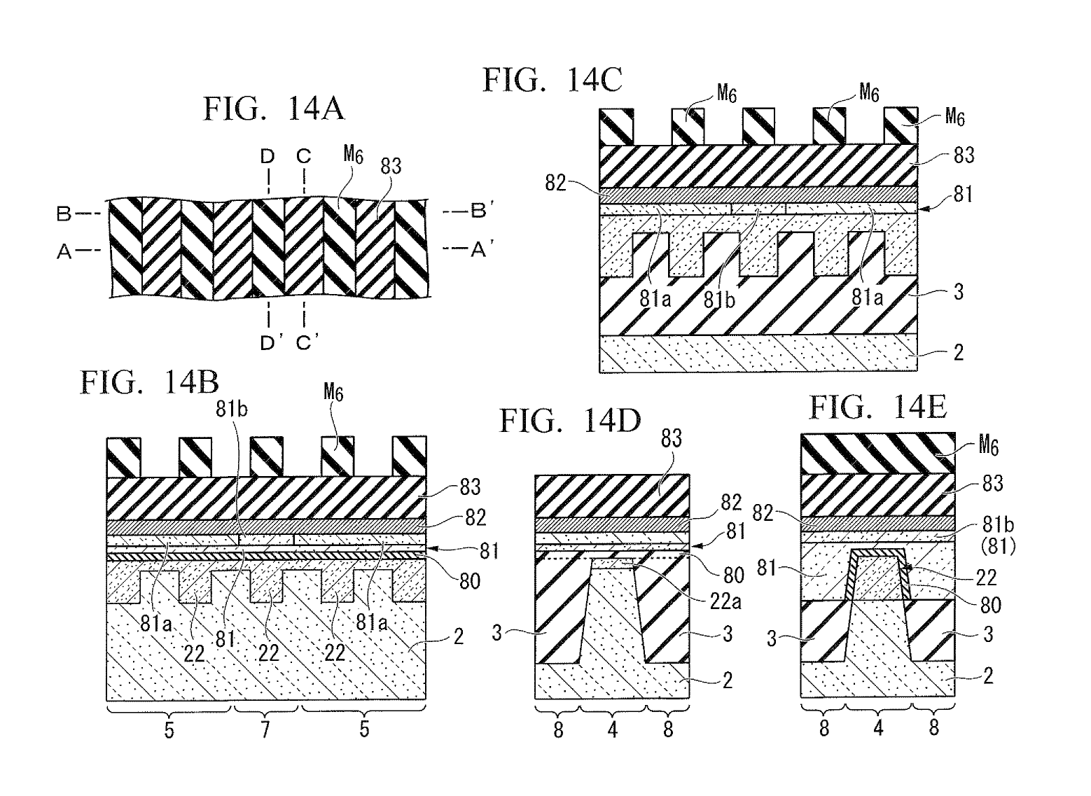

As shown in FIG. 14, a metal layer 82 and an insulating layer 83 made of, for example, a silicon nitride film are sequentially layered on the entire surface of the polysilicon film 81 with the mask layer M₅ removed. A mask layer M₆ made of photoresist is formed on the insulating film 83. The mask layer M₆ is formed in a zonal manner so as to cross over multiple fins 22 formed in the active region 4. After the metal layer 82 is formed, a thermal treatment for modifying the metal layer 82 may be performed, for example, at 800° C. for 30 seconds.

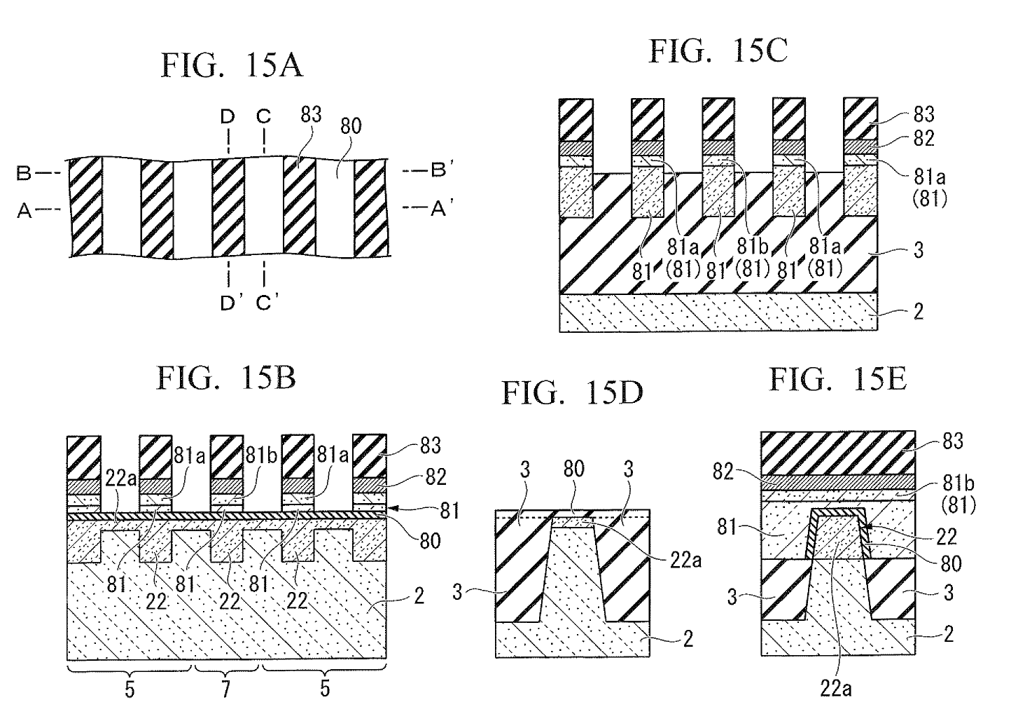

As shown in FIG. 15, the insulating layer 83 is dry etched and patterned with the mask layer M₆ as a mask. The metal layer 82 and the polysilicon film 81 are sequentially dry etched and patterned with the patterned insulating layer 83 as a mask. The N doped portion 81a into which the N-type dopant is injected and the P doped portion 81b into which the P-type dopant is injected are separated from each other by the patterning of the polysilicon film 81. The metal layer 82 is separated into a metal layer 21b to be a part of the dummy gate electrode 21 and a metal layer 41b to be a part of the gate electrode 41. The insulating layer 83 is separated into an insulating layer 21c covering the dummy gate electrode 21 and an insulating layer 41c covering the gate electrode 41.

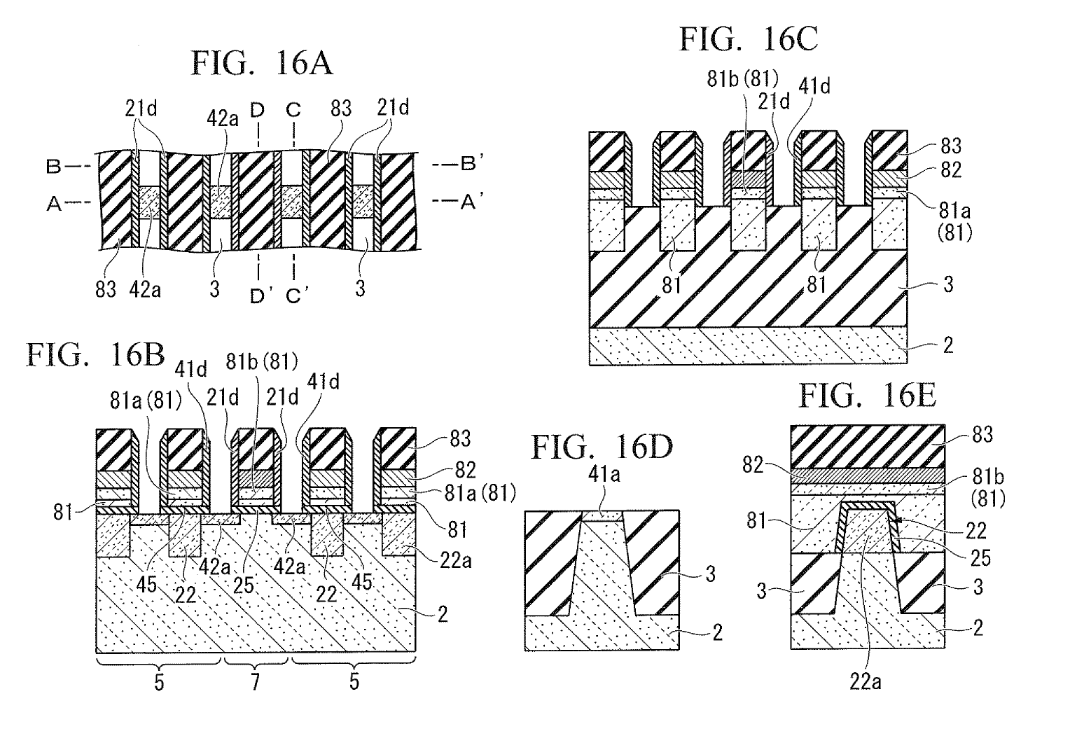

As shown in FIG. 16, an N-type impurity is ion-injected into the active region 4 on the semiconductor substrate 2 under the insulating film 80 with the insulating layer 83 as a mask, and thereby forming extension regions 42a in the active region 4 that are low concentration regions. A thermal treatment (diffusion process) for diffusing the dopant in the polysilicon film 81 is performed after the extension regions 42a are formed. Preferably, the thermal treatment is performed, for example, at 950° C. for 10 seconds. The thermal treatment is performed after the polysilicon film 81 is separated, resulting in no possibility that the p-type dopant and the N-type dopant will be mutually diffused.

An insulating film made of, for example, a silicon nitride and for sidewalls is formed on the semiconductor substrate 2 and etched back, thereby forming sidewalls 21d and 41d on the side surfaces of the layered body consisting of the polysilicon film 81, the metal layer 82, and the insulating layer 83.

The insulating film 80 is dry etched with the insulating film 83 and the sidewalls 21d as masks. Thereby, the insulating film 80 is separated, and the dummy-gate insulating film 25 and the gate insulating film 45 are formed on the channel stopper 7 and the element forming section 5.

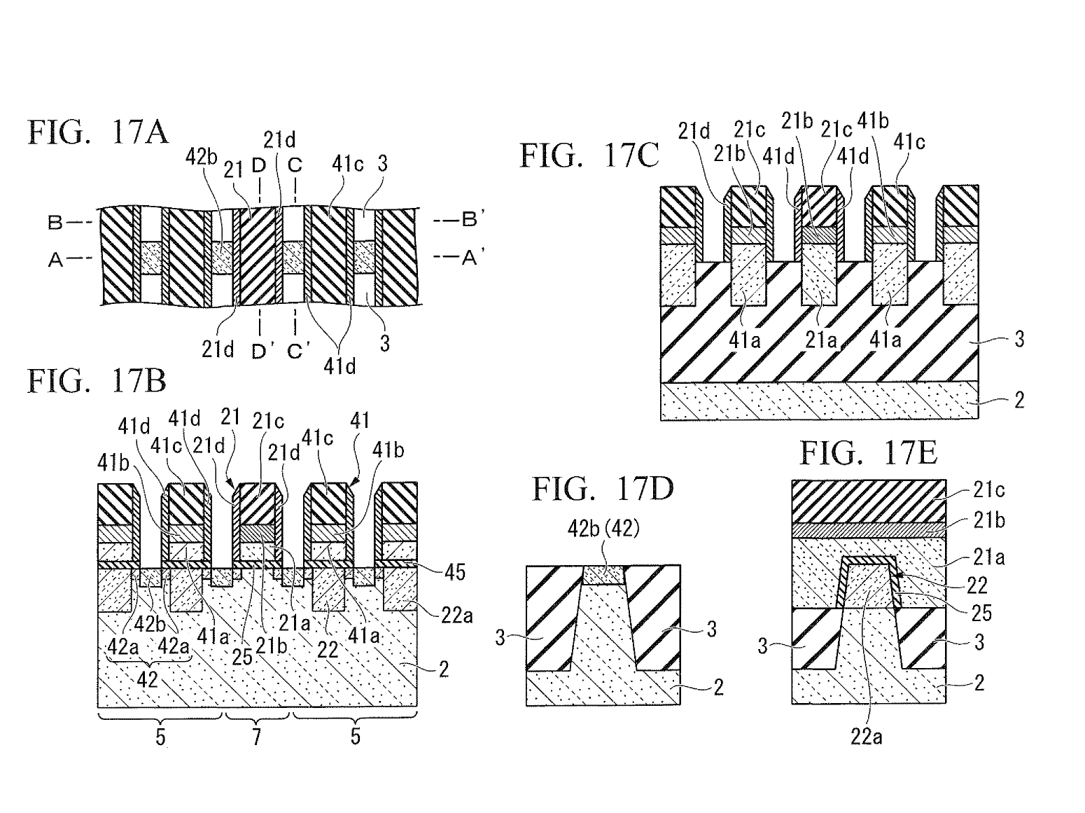

As shown in FIG. 17, an N-type impurity such as phosphorus is ion-injected into the active region 4 on the semiconductor substrate 2 with the insulating layer 83 and the sidewalls 21d as masks. Thereby, contact regions 42b that are high concentration regions are formed in the active region 4. As a result, the source drain regions 42 having the LDD structure are formed. After the contact regions 42b are formed, a thermal treatment (diffusion process) for further diffusing the dopant in the polysilicon film 81 is performed. Preferably, the thermal treatment is performed, for example, at 900° C. for 10 seconds.

In this manner, the polysilicon layer 21a including the P-type dopant and the metal layer 21b are sequentially layered, thereby forming the dummy gate electrode 21. At the same time, the polysilicon layer 41a including the N-type dopant and the metal layer 41b are sequentially layered, thereby forming the gate electrode 41.

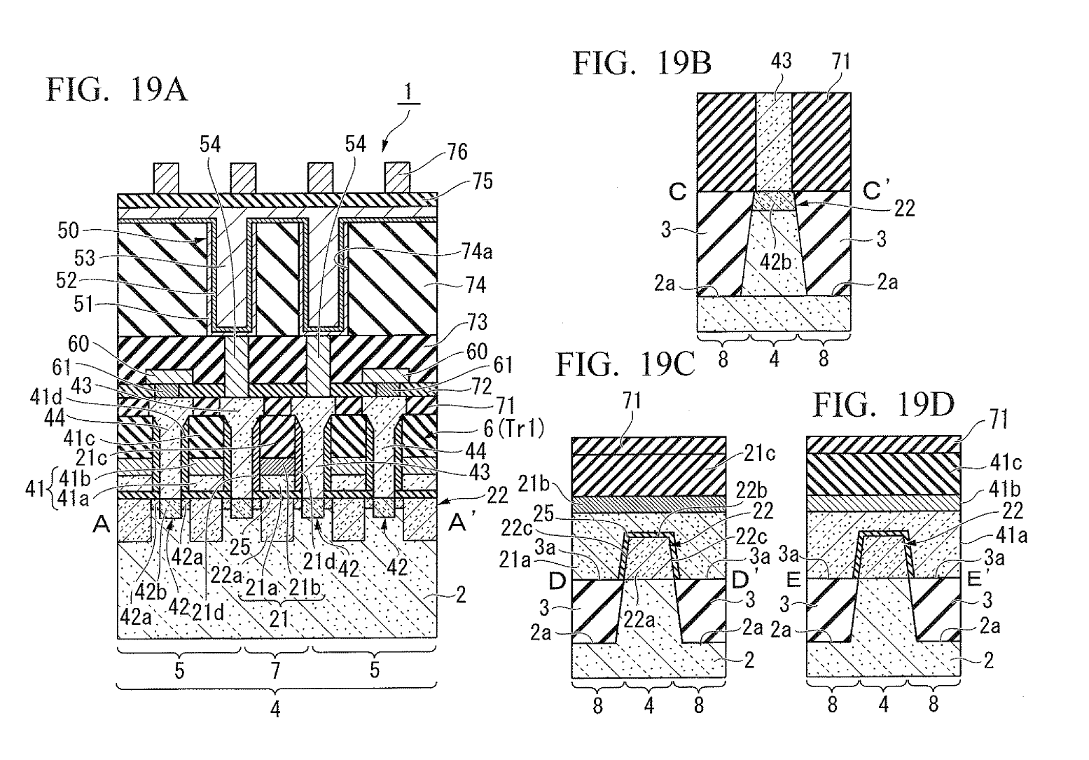

As shown in FIG. 19, a first inter-layer insulating film 71 covering the dummy gate electrode 21 and the gate electrode 41 is layered, and then, contact holes 43a and 44a are formed on the first inter-layer insulating film 71. Then, contact plugs 43 and 44 made of a doped polysilicon layer are formed in the contact holes 43a and 44a. After the contact plugs 43 and 44 are formed, a thermal treatment (diffusion process) for stabilizing the resistivity of the contact plugs 43 and 44 is performed, for example, at 1000° C. for 10 seconds. Due to the thermal treatment, the polysilicon layers 21a and 41a of the dummy gate electrode 21 and the gate electrode 41 are activated.

As shown in FIG. 19, a second inter-layer insulating film 72 is layered on the first inter-layer insulating film 71, and a bit-line contact plug 61 is formed in the second inter-layer insulating film 72. As a result, the bit line 60 and the source drain region 42 are connected to each other through the bit-line contact plug 61 and the contact plug 44.

A third inter-layer insulating film 73 is layered so as to cover the second inter-layer insulating film 72 and the bit line 60, and a capacity contact plug 54 is formed in the third inter-layer insulating film 73.

A fourth inter-layer insulating film 74 is layered so as to cover the third inter-layer insulating film 73, and a cylinder hole 74a is provided in the fourth inter-layer insulating film 74. The position of the cylinder hole 74a is determined such that the capacity contact plug 54 is exposed at the bottom surface of the cylinder hole 74a. Further, a lower electrode layer 51, a dielectric layer 52 and an upper electrode layer 53 are formed in the cylinder hole 74a. In this manner, the capacitor 50 is formed. The lower electrode layer 51 and the capacity contact plug 54 are connected to each other by forming the lower electrode layer 51. As a result, the lower electrode layer 51 of the capacitor 51 and the source drain region 42 are connected to each other through the capacity contact plug 54 and the contact plug 43.

A fifth inter-layer insulating film 75 is layered on the upper electrode layer 53, and a wiring layer 76 is formed on the fifth inter-layer insulating film 75.

In this manner, the semiconductor device 1 shown in FIGS. 1 to 4 is manufactured.

As explained above, according to the semiconductor device 1 of the first embodiment, the element forming section 5 and the channel stopper 7 are provided in the active region 4 Thereby, the active regions 4 need not be minutely insulated from one another by the element isolation insulating film 3. As a result, the areas of the source drain regions 42 do not decrease even if the width of the active region 4 is narrowed, thereby preventing an increase in the contact resistance of the contact plugs 43 and 44.

Additionally, the channel stopper 7 includes the fin 22, the dummy-gate insulating film 25, and the dummy gate electrode 21 straddling the fin 22, and the dummy gate electrode 21 opposes the upper surface 22b and the two side surfaces 22c of the fin 22. Thereby, the on-state suppression effect is reflected on the upper surface 22b and the two side surfaces 22c of the fin 22, and element isolation can be more certainly achieved in an off state.

Furthermore, according to the semiconductor device 1, the semiconductor element is preferably an MOS transistor. Thereby, MOS transistors are certainly insulated from each other, and the higher integration of the semiconductor device 1 can be achieved.

Moreover, according to the semiconductor device, the semiconductor element is the n-type MOS transistor, the dummy gate electrode is the polysilicon layer 21a including the p-type dopant, and a P-type polysilicon gate of a large work function is used. Thereby, the channel stopper 7 is prevented from being in an on-state, and therefore, the n-type transistors can be certainly isolated from each other.

According to the method of manufacturing the semiconductor device 1, the element forming section 5 and the channel stopper 7 are provided in the active region 4. Thereby, the active regions 4 need not be minutely insulated from one another by the element-isolation insulating film 3. As a result, the areas of the source drain regions 42 do not decrease even if the width of the active region 4 is narrowed, thereby preventing an increase in the contact resistance of the contact plugs 43 and 44.

Additionally, according to the method of manufacturing the semiconductor device 1, the dummy-gate insulating film 25 and the gate insulating film 45 are formed at the same time, the dummy gate electrode 21 and the gate electrode 41 are formed at the same time, and then, the source drain regions 42 are formed. Thereby, the channel stopper 7 and the element forming section 5 can be formed at the same time, and the manufacturing process of the semiconductor device 1 can be shortened.

Furthermore, according to the method of manufacturing the semiconductor device 1, the polysilicon film 81 is layered on the semiconductor substrate 2, and then, the polysilicon film 81 is patterned to form the dummy gate electrode 21 and the gate electrode 41. Thereby, the manufacturing process of the semiconductor device 1 can be shortened.

Moreover, according to the method of manufacturing the semiconductor device 1, the P-type dopant and the N-type dopant are sequentially injected into the portions to be the dummy gate electrode 21 and the gate electrode 41 in the polysilicon film 81, the polysilicon film 81 is patterned, and then a thermal treatment is performed to diffuse each dopant. Thereby, there is no possibility that different dopants will mutually diffuse between the dummy gate electrode 21 and the gate electrode 41, and the resistances of the dummy gate electrode 21 and the gate electrode 41 can be reduced. Additionally, the dummy gate electrode 21 and the gate electrode 41 can be a p-type semiconductor and an n-type semiconductor, respectively.

### Second Embodiment

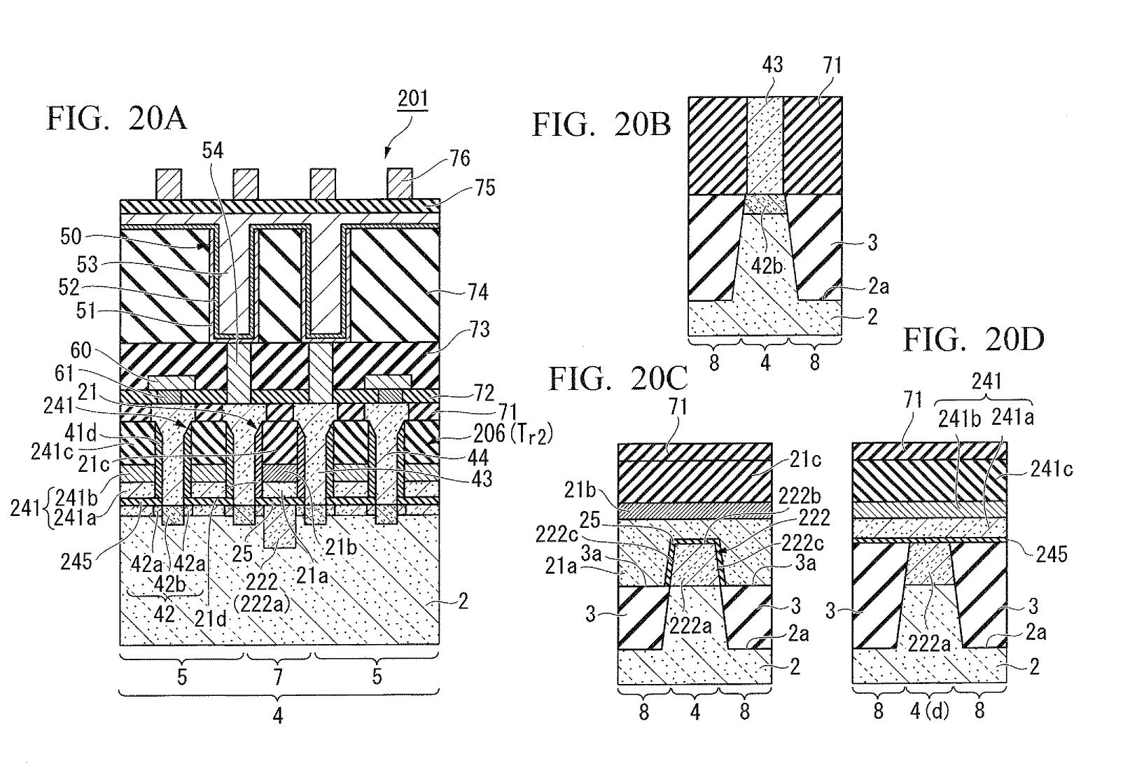

Hereinafter, a semiconductor device according to a second embodiment of the present invention is explained with reference to FIG. 20.

FIG. 20A is a cross-sectional view along the A-A′ line shown in FIG. 1, FIG. 20B is a cross-sectional view along the C-C′ line shown in FIG. 15 FIG. 20C is a cross-sectional view along the D-D′ line shown in FIG. 1, and FIG. 20D is a cross-sectional view along the E-E′ line shown in FIG. 1. The same elements as those shown in FIGS. 1 to 3 are appended the same reference numerals, and the explanation thereof will be omitted, or briefly given.

A semiconductor device 201 shown in FIG. 20 includes active regions 4 insulated from one another by an element-isolation insulating film 3 embedded on a semiconductor substrate 2, multiple element forming sections 5 provided in each active region 4, a semiconductor element 206 formed in each element forming section 5, and a channel stopper 7 provided in the active region 4 for insulating element forming sections 5 from each other. The semiconductor device 201 according to the second embodiment is an example where a planar MOS transistor is applied to the semiconductor element 206.

As shown in FIG. 20, the element-isolation insulating film 3 is embedded on a trench 2a provided on the semiconductor substrate 2, and the region of the element-isolation insulating film 3 is regarded as an STI-element isolation region 8. Additionally, multiple active regions 4, each of which is a part of the semiconductor substrate 2 and which are insulated from one another by the STI-element isolation region 8, are formed on the semiconductor substrate 2.

As shown in FIG. 20, the semiconductor device 201 includes a dummy gate electrode 21 and a gate electrode 241. The dummy gate electrode 21 and the gate electrode 241 cross over the multiple active regions 4. The dummy gate electrode 21 is arranged so as to pass through the channel stopper 7 in the active region 4. On the other hand, the gate electrode 241 is arranged so as to pass through the element forming section 5 in the active region 4.

As shown in FIG. 20, the source drain regions 42 are formed on both sides of each gate electrode 241. One gate electrode 241 and the two source drain regions 42 on both sides thereof form one MOS transistor.

Hereinafter, the channel stopper 7 is explained. As shown in FIG. 20, the channel stopper 7 includes a fin 222 provided in the active region 4, a dummy-gate insulating film 25 covering the fin 222, and a dummy gate electrode 21 straddling the fin 222.

Grooves 3a are provided in the element-isolation insulating films 3 on both sides of the active region 4, and thereby form the fin 222 protruding between the grooves 3a. The fin 222 is formed only at the channel stopper 7 in the active region 4. The well region 222a constituting the channel region is formed in the active region 4 including the fin 222. The well region 222a is formed by injecting a p-type dopant such as boron into the active region 4. The amount of the dopant injected into the well region 222a is suppressed to the extent that leaks at the junction do not increase significantly.

The dummy-gate insulating film 25 is formed on the fin 222. The dummy-gate insulating film 25 is formed on an upper surface 222b of the fin 222 and side surfaces 222c exposed by forming the grooves 3a.

A part of the dummy gate electrode 21 is embedded on the grooves 3a provided in the element-isolation insulating film 3. Thereby, the dummy gate electrode 21 straddles the fin 222.

The dummy gate electrode 21 is embedded on the grooves 3a and includes a polysilicon layer 21a covering the upper surface 222b of the fin 222 and a metal layer 21b layered on the polysilicon layer 21a. The p-type dopant such as boron is doped in the polysilicon layer 21a at a high concentration. As a result, the polysilicon layer 21a of the dummy gate electrode 21 is a P⁺ semiconductor.

The polysilicon layer 21a is embedded on the grooves 3a, and thereby arranged so as to oppose the upper surface 222b and side surfaces 222c of the fin 222 through the dummy-gate insulating film 25. As a result, the channel stopper 7 has a fin-type channel structure in which the dummy gate electrode 21 straddles the fin 222. The polysilicon layer 21a is arranged so as to oppose the upper surface 222b and the side surfaces 222c of the fin 222, thereby preventing current from leaking from the side surface 222c. Therefore, the on-state suppression effect is reflected on the upper surface 222b and the two side surfaces 222c, and element isolation can be certainly achieved in an off-state.

Hereinafter, the configuration of an n-type planar MOS transistor Tr₂ formed in the element forming section 5 is explained As shown in FIG. 20, the n-type planar MOS transistor Tr₂ (hereinafter, “transistor Tr₂”) includes a gate insulating film 245 formed in the active region 4, and a gate electrode 241 layered through the gate insulating film 245. The well region 222a is formed in the active region 4 under the gate insulating film 245.

The gate insulating film 245 may be a silicon oxide film, a silicon oxynitride film, an Hf dielectric film respectively formed by performing the thermal oxidation process, the thermal oxynitridation process, and the CVD for the surface of the active region 4. Preferably, the material of the gate insulating film 245 is the same as that of the dummy-gate insulating film 25.

The gate electrode 241 includes a polysilicon layer 241a layered on the gate insulating film 245 and a metal layer 241b layered on the polysilicon layer 241a. The n-type dopant such as phosphorus is doped in the polysilicon layer 241a. An insulating layer 41c made of, for example, a silicon nitride is layered on the metal layer 241b, and sidewall films 41d made of, for example, a silicon nitride is formed on both sides of the polysilicon layer 241a and the metal layer 241b.

The polysilicon layer 241a is formed on the gate insulating film 245, and thereby arranged so as to oppose the active region 4 through the gate insulating film 245. As a result, the planar channel structure is provided.

The source drain regions 42 are formed on both sides of the gate electrode 241. The source drain region 42 includes an extension region 42a formed below the sidewall film 41d, and a contact region 42b formed at a position not overlapping the sidewall film 41d. Thus, the LDD structure is formed in the transistor Tr₂ of the second embodiment.

As explained above, the planar MOS transistor Tr₂ may be used as the semiconductor element 206 in the present invention.

Additionally, the same processes as those in the first embodiment except for forming the fin 222 only at the portion to be the channel stopper 7 can be performed to manufacture the semiconductor device 201 including the planar MOS transistor Tr₂.

### Third Embodiment

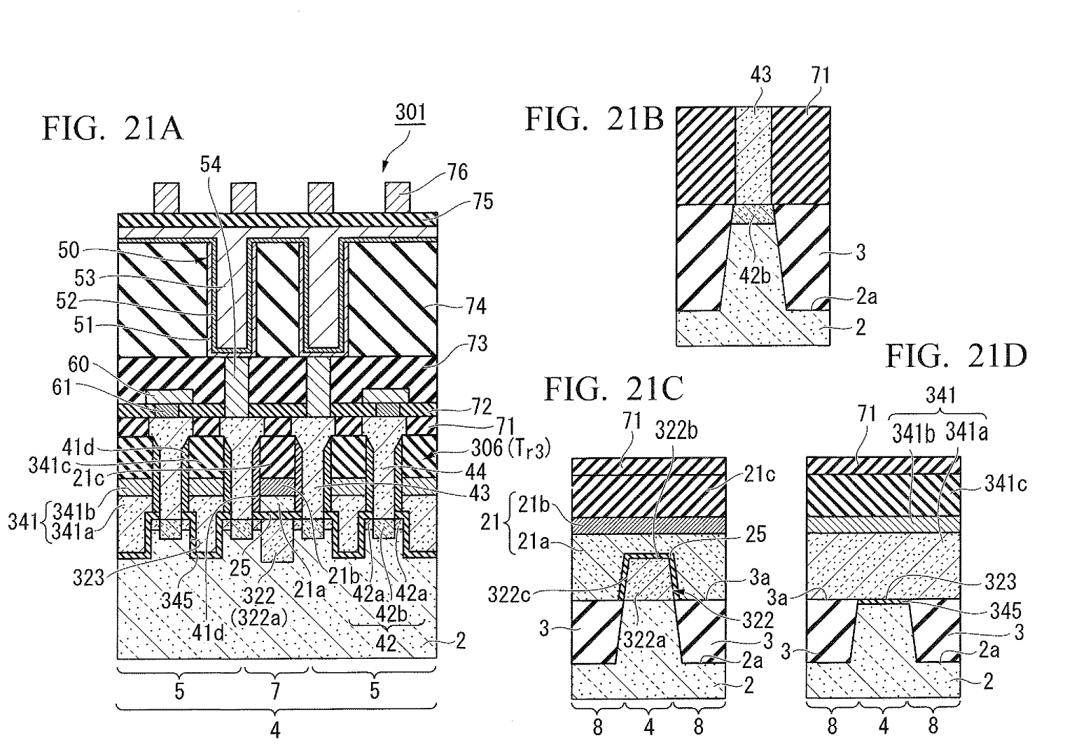

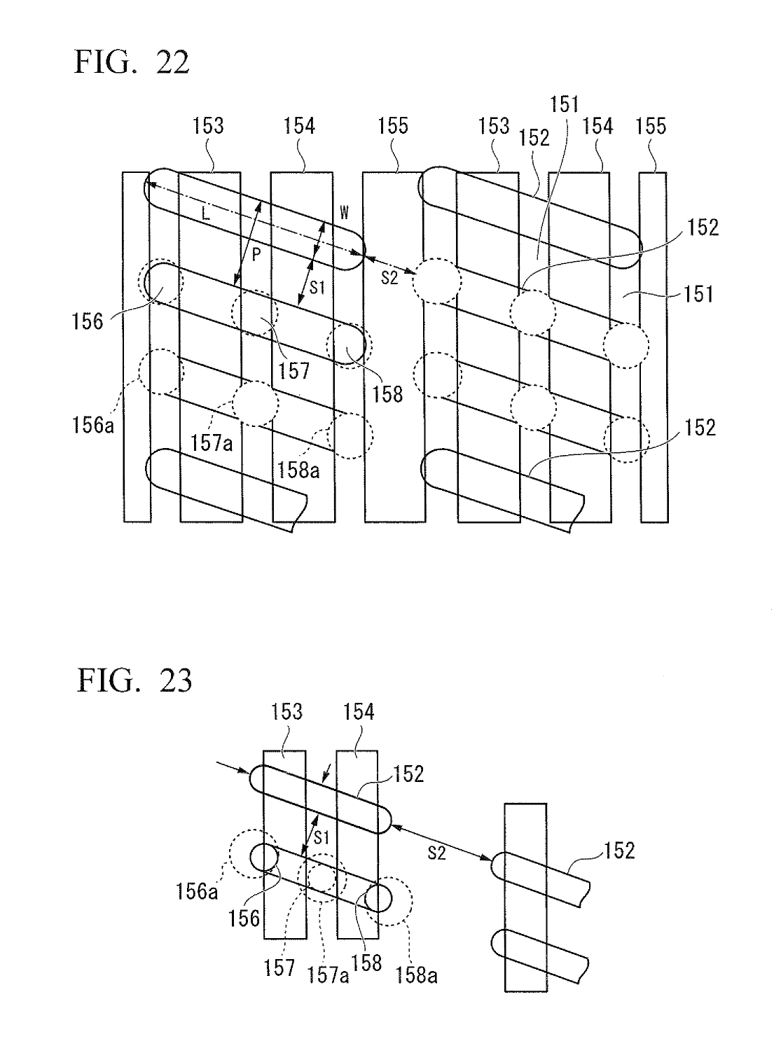

Hereinafter, a semiconductor device according to a third embodiment of the present invention is explained with reference to FIG. 21.

FIG. 21A is a cross-sectional view along the A-A′ line shown in FIG. 1, FIG. 21B is a cross-sectional view along the C-C′ line shown in FIG. 1, FIG. 21C is a cross-sectional view along the D-D′ line shown in FIG. 1, and FIG. 21D is a cross-sectional view along the E-E′ line shown in FIG. 1. The same elements as those shown in FIGS. 1 to 3 are appended the same reference numerals, and the explanation thereof will be omitted, or briefly given.

A semiconductor device 301 shown in FIG. 21 includes active regions 4 insulated from one another by element-isolation insulating films 3 embedded on a semiconductor substrate 2, multiple element forming sections 5 provided in each active region 4, a semiconductor element 306 formed in each element forming section 5, and a channel stopper 7 provided in the active region 4 for insulating element forming sections 5 from each other. The semiconductor device 301 according to the third embodiment is an example where a trench MOS transistor is applied to the semiconductor element 306.

As shown in FIG. 21, the element-isolation insulating film 3 is embedded on a trench 2a provided on the semiconductor substrate 2, and the region of the element-isolation insulating film 3 is regarded as an STI-element isolation region 8. Additionally, multiple active regions 4, each of which is a part of the semiconductor substrate 2 and which are insulated from one another by the STI-element isolation region 8, are formed on the semiconductor substrate 2.

As shown in FIG. 21, the semiconductor device 301 includes a dummy gate electrode 21 and a gate electrode 341. The dummy gate electrode 21 and the gate electrode 341 cross over the multiple active regions 4. The dummy gate electrode 21 is arranged so as to pass through the channel stopper 7 in the active region 4. On the other hand, the gate electrode 341 is arranged so as to pass through the element forming section 5 in the active region 4.

As shown in FIG. 21, source drain regions 42 are formed on both sides of each gate electrode 341. One gate electrode 341 and two source drain regions 42 on both sides thereof form one MOS transistor.

Hereinafter, the channel stopper 7 is explained. As shown in FIG. 21, the channel stopper 7 includes a fin 322 provided in the active region 4, a dummy-gate insulating film 25 covering the fin 322, and a dummy gate electrode 21 straddling the fin 322.

Grooves 3a are provided in the element-isolation insulating films 3 on both sides of the active region 4, thereby form a fin 322 protruding between the grooves 3a. The fin 322 is formed only at the channel stopper 7 in the active region 4. The well region 322a constituting the channel region is formed in the active region 4 including the fin 322. The well region 322a is formed by injecting a p-type dopant such as boron into the active region 4. The amount of the dopant injected into the well region 322a is suppressed to the extent that leaks at the junction do not increase significantly.

The dummy-gate insulating film 25 is formed on the fin 322. The dummy-gate insulating film 25 is formed on an upper portion 322b of the fin 322 and side surfaces 322c exposed by forming the grooves 3a.

Apart of the dummy gate electrode 21 is embedded on the grooves 3a provided in the element-isolation insulating film 3. Thereby, the dummy gate electrode 21 straddles the fin 322.

The dummy gate electrode 21 is embedded on the grooves 3a and includes a polysilicon layer 21a covering the upper surface 322b of the fin 322 and a metal layer 21b layered on the polysilicon layer 21a. The p-type dopant such as boron is doped in the polysilicon layer 21a at a high concentration. As a result, the polysilicon layer 21a of the dummy gate electrode 21 is a P⁺ semiconductor.

The polysilicon layer 21a is embedded on the grooves 3a, and thereby arranged so as to oppose the upper surface 322b and side surfaces 322c of the fin 322 through the dummy-gate insulating film 25. As a result, the channel stopper 7 has a fin-type channel structure in which the dummy gate electrode 21 straddles the fin 322. The polysilicon layer 21a is arranged so as to oppose the upper surface 322b and the side surfaces 322c of the fin 322, thereby preventing current from leaking from the side surfaces 322c. Therefore, the on-state suppression effect is reflected on the upper surface 322b and the two side surfaces 322c, and element isolation can be certainly achieved in an off-state.

Hereinafter, the configuration of an n-type trench MOS transistor Tr₃ formed in the element forming section 5 is explained. As shown in FIG. 21 the n-type trench MOS transistor Tr₃ (hereinafter, “transistor Tr₃”) includes a trench 323 formed in the active region 4, a gate insulating film 345 covering the inner surface of the trench 323 and a gate electrode 341, a part of which is embedded in the trench 323 through the gate insulating film 345.

The trench 323 is formed by the grooves 3a formed in the element-isolation insulating film 3 penetrating through the active region 4. Therefore, the grooves 3a and the trench 323 are connected to each other. A well region constituting the channel region is provided at the trench 323 in the element forming section 5.

The gate insulating film 345 is formed on the inner surface of the trench 323. The gate insulating film 345 may be a silicon oxide film, a silicon oxynitride film, an Hf dielectric film respectively formed by performing the thermal oxidation process, the thermal oxynitridation process, and the CVD for the surface of the inner surface of the trench 323. Preferably, the material of the gate insulating film 345 is the same as that of the dummy gate insulating film 25.

The gate electrode 341 includes a polysilicon layer 341a, a part of which is embedded in the trench 323, and a metal layer 341b layered on the polysilicon layer 341a. The n-type dopant such as phosphorus is doped in the polysilicon layer 341a. An insulating layer 341c made of, for example, a silicon nitride film is layered on the metal layer 341b, and a sidewall film 41d made of, for example, a silicon nitride film is formed on both sides of the polysilicon layer 341a and the metal layer 341b.

The polysilicon layer 341a is embedded in the trench 323, and thereby arranged so as to oppose the inner surface of the trench 323 through the gate insulating film 345. As a result, the trench channel structure in which the gate electrode 341 is embedded in the trench 323 is provided. The channel length is extended due to the structure. Therefore, the short channel effect can be suppressed even in the case of the higher integration of MOS transistors.

The source drain regions 42 are formed in the active region 4 and on both sides of the gate electrode 341. The source drain region 42 includes an extension region 42a formed below the sidewall film 41d and a contact region 42b formed at a position not overlapping the sidewall film 41d. Thus, the LDD structure is formed in the transistor Tr₃ of the third embodiment.

As explained above, the trench MOS transistor Tr₃ may be used as the semiconductor element 306 in the present invention.

To manufacture the semiconductor device 301 including the trench MOS transistor Tr₃, the grooves 3a crossing the active region 4 are formed in the element-isolation insulating film 3 on both sides of the active region 4 in the widthwise direction. As a result, the fin 322 is formed at the portion to be the channel stopper 7. Then, the active region 4 that is to be the element forming section 5 is dry etched. Thereby, the trench 323 communicated with the grooves 3a on both sides of the active region 4 in the widthwise direction is formed. Then, the same processes as those in the first embodiment may be performed.

It is explained in the first to the third embodiments that the P-type dopant and the N-type dopant are sequentially injected in the polysilicon film 81 after the polysilicon film 81 is layered, and then the polysilicon layer 81 is patterned, and thereby the dummy gate electrode 21 having the polysilicon layer 21a including the P-type dopant and a gate electrode 41 having the polysilicon layer 41a including the N-type dopant are formed. However, the following processes may be used in the present invention.

As a first example, the polysilicon film is layered on the semiconductor substrate after the gate insulating film and the dummy-gate insulating film are formed. Then, the metal layer and the insulating layer are layered on the polysilicon layer without injecting the P-type dopant and the N-type dopant. Then, the polysilicon layer, the metal layer, and the insulating layer are patterned to form the dummy gate electrode and the gate electrode. Then, the source drain region is formed in the active region on both sides of the gate electrode. The semiconductor device may be manufactured in this manner.

As a second example, the polysilicon film is layered on the semiconductor substrate after the gate insulating film and the dummy-gate insulating film are formed, and then, the polysilicon film is patterned. Then, a dopant is injected into the patterned polysilicon film and the active region exposed between the polysilicon films at the same time. Thereby, the resistance of the polysilicon film is reduced to form the dummy gate electrode and the gate electrode. At the same time, the source drain regions are formed on both sides of the gate electrode. In this case, the same dopant is injected into the dummy gate electrode, the gate electrode, and the source drain regions. The semiconductor device may be manufactured in this manner.

As a third example, a doped polysilicon film including the P-type dopant, for example, is layered on the semiconductor substrate after the gate electrode and the dummy gate electrode are formed. Then, the N-type dopant is injected into the portion in the doped polysilicon film that is to be the gate electrode. Then, the doped polysilicon film is patterned and a thermal treatment is performed to diffuse the dopant. Thereby, the dummy gate electrode including the polysilicon layer including the P-type dopant and the gate electrode including the polysilicon layer including the N-type dopant are formed. Then, the source drain regions are formed in the active region on both sides of the gate electrode. The semiconductor device may be manufactured in this manner.

It is apparent that the present invention is not limited to the above embodiments, but may be modified and changed without departing from the scope and spirit of the invention.

What is claimed is:

1. A semiconductor device, comprising:
an active region that is insulated by an element isolation insulating film embedded on a semiconductor substrate;
a plurality of element forming sections that are provided in the active region;
a semiconductor element that is formed in each of the element forming sections; and
a channel stopper that is provided in the active region to insulate the element forming sections from each other, wherein
the channel stopper comprises:
a fin that protrudes between grooves provided in the element-isolation insulating film and on both sides of the active region;
a dummy-gate insulating film that covers the fin; and
a dummy gate electrode that straddles the fin.

2. The semiconductor device according to claim 1, wherein the semiconductor element is an MOS transistor.

3. The semiconductor device according to claim 1, wherein
the semiconductor element is an n-type MOS transistor, and
the dummy gate electrode includes a doped polysilicon layer including a p-type dopant.

4. The semiconductor device according to claim 1, wherein the semiconductor element is a fin-type MOS transistor comprising:
the fin;
a gate insulating film that covers the fin;
a gate electrode that straddles the fin through the gate insulating film; and
source drain regions that are provided at the fin on each side of the gate electrode.

5. A method of manufacturing a semiconductor device including a plurality of element forming sections provided in an active region on a semiconductor substrate, a semiconductor element formed in each of the element forming sections, and a channel stopper provided in the active region to insulate the element forming sections from each other, the method comprising:
embedding an element-isolation insulating film on the semiconductor substrate to form the active region;
providing grooves in the element-isolation insulating film and at least on both sides of a portion to be the channel stopper to form a fin protruding between the grooves;
forming a dummy-gate insulating film that covers the fin; and
forming a dummy gate electrode so as to straddle the fin through the dummy-gate insulating film.

6. The method according to claim 5, further comprising after the forming of the fin:
forming a gate insulating film in each of the element forming sections at the same time as the forming of the dummy-gate insulating electrode;
forming a gate electrode on the gate insulating film at the same time as the forming of the dummy gate; and
forming source drain regions in the active region and on both sides of the gate electrode to form an MOS transistor as the semiconductor element in each of the element forming sections.

7. The method according to clam 6, wherein the forming of the dummy gate electrode comprises:
layering a silicon film on the semiconductor substrate after the dummy-gate insulating film and the gate insulating film are formed; and
patterning the silicon film to form the dummy gate electrode and the gate electrode.

8. The method according to claim 6, wherein the forming of the deny gate electrode comprises:
layering a silicon film on the semiconductor substrate after the dummy-gate insulating film and the gate insulating film are formed;
injecting different dopants sequentially into a portion in the silicon film that is to be the dummy gate electrode and a portion in the silicon film that is to be the gate electrode;
patterning the silicon film after the different dopants are injected to form the dummy gate electrode and the gate electrode; and
performing a thermal treatment to diffuse each of the sequentially injected dopants in the dummy gate electrode and the gate electrode.

9. The method according to claim 6, wherein the forming of the dummy gate electrode comprises:
layering a silicon film on the semiconductor substrate after the dummy-gate insulating film and the gate insulating film are formed;
patterning the silicon film to form the dummy gate electrode and the gate electrode; and
injecting a dopant into the dummy gate electrode, the gate electrode, and the active region to form the source drain regions at the same time.

10. The method according to claim 6, wherein the forming of the dummy gate electrode comprise:
layering a silicon film including a dopant on the semiconductor substrate after the dummy-gate insulating film and the gate insulating film are formed;
injecting a dopant different from the dopant included in the silicon film into a portion to be the gate electrode and in the silicon film including the dopant; and
patterning the silicon film to form the dummy gate electrode and the gate electrode.

11. The method according to claim 5, wherein
the semiconductor element is an n-type MOS transistor, and
the dummy gate electrode is a doped polysilicon layer including a p-type dopant.
